(19) United States
(12) Patent Application Publication
(10) Pub. No.: US 2026/0198201 A1
(43) Pub. Date: Jul. 9, 2026

(54) DISPLAY PANEL AND DISPLAY APPARATUS

(71) Applicant: HKC CORPORATION LIMITED, SHENZHEN (CN)

(72) Inventors: JIAXING WU, SHENZHEN (CN); JUN ZHANG, SHENZHEN (CN); YUANYING WANG, SHENZHEN (CN); PEI XU, SHENZHEN (CN)

(21) Appl. No.: 19/428,330

(22) Filed: Dec. 22, 2025

(30) Foreign Application Priority Data
Jan. 6, 2025 (CN) 202510013550.5

(51) Int. Cl. H10K 59/50; G06F 3/041; H10K 59/12; H10K 59/127; H10K 59/131; H10K 59/35; H10K 59/40; H10K 59/80

(52) U.S. Cl. CPC H10K 59/50; G06F 3/04164; H10K 59/1201; H10K 59/127; H10K 59/131; H10K 59/35; H10K 59/40; H10K 59/8791

(57) ABSTRACT

A display panel and a display apparatus are provided. The display panel may include a first substrate, a second substrate, a light modulation structure, a first electrode, a second electrode, a first sub-pixel and a second sub-pixel. The light modulation structure may be arranged between the first substrate and the second substrate. A plurality of first grooves may be defined on a side close to the first substrate, and a plurality of second grooves may be defined on a side close to the second substrate. The first grooves and second grooves may be alternately defined. The first electrode may be arranged on a side of the light modulation structure close to the first substrate. The second electrode may be arranged on the side of the light modulation structure close to the second substrate.

### CROSS REFERENCE TO RELATED APPLICATIONS

This application claims priority to Chinese Patent Application No. 202510013550.5, filed on Jan. 6, 2025, which is herein incorporated by reference in its entirety.

### TECHNICAL FIELD

The present disclosure relates to the field of display technologies, and in particular to a display panel and a display apparatus.

### BACKGROUND

With continuous development of display technologies, an organic light-emitting diode (OLED) display technology has gradually become a predominant display technology due to its advantages such as a fast response speed, a wide operating temperature range, a high contrast ratio, a great viewing angle, and an ability to achieve flexible display and transparent display.

At present, OLED display panels capable of realizing double-sided display functions may generally require electrochromic materials and control electrodes on both sides, resulting in high circuit complexity, increased panel thickness, and an inability to meet narrow-view anti-peeping requirements.

### SUMMARY

According to a first aspect of the present disclosure, a display panel may be provided. The display panel may include: a first substrate, a second substrate, a light modulation structure, a first electrode, a second electrode, a plurality of first sub-pixels, and a plurality of second sub-pixel. The second substrate may be arranged opposite to the first substrate. The light modulation structure may be arranged between the first substrate and the second substrate. The plurality of first grooves may be defined on a side of the light modulation structure close to the first substrate, and a plurality of the second grooves may be defined on a side of the light modulation structure close to the second substrate. The plurality of first grooves and the plurality of the second grooves may be alternately defined in sequence along each of a first direction and a second direction. The first direction and the second direction may be parallel to the light modulation structure. The first direction and the second direction intersect with each other. The first electrode may be arranged on the side of the light modulation structure close to the first substrate. The second electrode may be arranged on the side of the light modulation structure close to the second substrate. The second electrode may be configured to form a preset electric field with the first electrode. The preset electric field may be configured to control a light transmittance of the light modulation structure. Each of the plurality of first sub-pixels may be arranged within one of the plurality of first grooves. Each of the plurality of second sub-pixels may be arranged within one of the plurality of second groove.

According to a second aspect of the present disclosure, a display apparatus may be provided. The display apparatus may include a display panel and a control circuit board. The control circuit board may be electrically connected to the display panel, and configured to control the display panel to display an image in a matched display mode. The display panel may include: a first substrate, a second substrate, a light modulation structure, a first electrode, a second electrode, a plurality of first sub-pixels, and a plurality of second sub-pixel. The second substrate may be arranged opposite to the first substrate. The light modulation structure may be arranged between the first substrate and the second substrate. The plurality of first grooves may be defined on a side of the light modulation structure close to the first substrate, and a plurality of the second grooves may be defined on a side of the light modulation structure close to the second substrate. The plurality of first grooves and the plurality of the second grooves may be alternately defined in sequence along each of a first direction and a second direction. The first direction and the second direction may be parallel to the light modulation structure. The first direction and the second direction intersect with each other. The first electrode may be arranged on the side of the light modulation structure close to the first substrate. The second electrode may be arranged on the side of the light modulation structure close to the second substrate. The second electrode may be configured to form a preset electric field with the first electrode. The preset electric field may be configured to control a light transmittance of the light modulation structure. Each of the plurality of first sub-pixels may be arranged within one of the plurality of first grooves. Each of the plurality of second sub-pixels may be arranged within one of the plurality of second groove.

### BRIEF DESCRIPTION OF THE DRAWINGS

In order to more clearly illustrate technical solutions in the present disclosure, the drawings required in the description of the embodiments will be briefly introduced below. Obviously, the drawings in the following description may be only some embodiments of the present disclosure. For those of ordinary skills in the art, other drawings could be obtained based on these drawings without creative efforts.

FIG. 1 is a schematic structural diagram of a first embodiment of a display panel according to the present disclosure.

FIG. 2 is a schematic planar structural diagram of an embodiment of a light modulation structure according to the present disclosure.

FIG. 3 is a schematic flow chart of an implementation of a preparation method of a display panel according to the present disclosure.

FIG. 4A is a schematic process chart matching operations S11 to S15 of FIG. 3.

FIG. 4B is a schematic process chart matching operations S21 to S24 of FIG. 3.

FIG. 5 is a schematic diagram of light emission of the display panel in the embodiment of FIG. 1 in the narrow-view double-sided display mode.

FIG. 6 is a schematic diagram of light emission of the display panel in the embodiment of FIG. 1 in the narrow-view single-sided display mode.

FIG. 7 is a schematic diagram of light emission of the display panel of the embodiment of FIG. 1 in the wide-view high-resolution display mode.

FIG. 8 is a schematic diagram of light emission of the display panel of the embodiment of FIG. 1 in the wide-view low-resolution display mode.

FIG. 9 is a schematic diagram of light emission of the display panel in the embodiment of FIG. 1 in the mixed high-and-low resolution display mode.

FIG. 10 is a schematic structural diagram of a second embodiment of a display panel according to the present disclosure.

FIG. 11 is a schematic planar structural diagram of an embodiment of the first electrode of FIG. 10.

FIG. 12 is a control timing diagram of a first electrode and a second electrode provided in an embodiment of the present disclosure.

FIG. 13 is a control timing diagram of the first electrode and the second electrode provided in another embodiment of the present disclosure.

FIG. 14 is a light emission state diagram of a display mode of the display panel in FIG. 10.

FIG. 15 is a schematic diagram of a planar positional relationship of various electrodes of a third embodiment of the display panel according to the present disclosure.

FIG. 16 is a schematic structural diagram of a third embodiment of a display panel according to the present disclosure.

FIG. 17 is a schematic structural diagram of a fourth embodiment of another display panel according to the present disclosure.

FIG. 18 is a schematic structural diagram of a fifth embodiment of a display panel according to the present disclosure.

FIG. 19 is a schematic flow chart of another embodiment of a preparation method of the display panel according to the present disclosure.

FIG. 20A is a schematic process chart matching operations S31 to S36 of FIG. 19.

FIG. 20B is a schematic process chart matching operations S41 to S45 of FIG. 19.

FIG. 21 is a schematic diagram of light emission of the display panel in the embodiment of FIG. 18 in the wide-view double-sided display mode.

FIG. 22 is a schematic diagram of light emission of the display panel in the embodiment of FIG. 18 in the wide-view single-sided display mode.

FIG. 23 is a schematic diagram of light emission of the display panel in the embodiment of FIG. 18 in the first narrow-view double-sided display mode.

FIG. 24 is another schematic diagram of light emission of the display panel in the embodiment of FIG. 18 in the first narrow-view double-sided display mode.

FIG. 25 is another schematic diagram of light emission of the display panel in the embodiment of FIG. 18 in the first narrow-view double-sided display mode.

FIG. 26 is a schematic structural diagram of a sixth embodiment of a display panel according to the present disclosure.

FIG. 27 is a schematic planar structural diagram of the first electrode of FIG. 26.

FIG. 28 is a schematic diagram of light emission of the display panel in FIG. 26 in a second wide-view display mode.

FIG. 29 is a schematic diagram of light emission of the display panel in FIG. 26 in the second narrow-view display mode.

FIG. 30 is a schematic structural diagram of a display panel in a seventh embodiment of the present disclosure.

FIG. 31 is a schematic planar structural diagram of a first electrode of FIG. 30.

FIG. 32 is a schematic diagram of light emission of the display panel in FIG. 30 in a double-sided first lateral view display mode.

FIG. 33 is a schematic diagram of light emission of the display panel in FIG. 30 in a double-sided second lateral view display mode.

FIG. 34 is a schematic diagram of light emission of the display panel in FIG. 30 in a double-sided dual-lateral view display mode.

FIG. 35A is another schematic planar structural diagram of the first electrode in FIG. 30.

FIG. 35B is a schematic planar structural diagram of the second electrode in FIG. 30.

FIG. 36 is a schematic diagram of light emission of the display panel of FIG. 30 in a mixed display mode.

FIG. 37 is a schematic display diagram of the display panel in FIG. 30 in an identification display mode.

FIG. 38 is a schematic display diagram of the display panel of FIG. 30 in another identification display mode.

FIG. 39 is a schematic structural view of an embodiment of a display apparatus according to the present disclosure.

### DETAILED DESCRIPTION

The technical scheme of embodiments of the present disclosure may be described in detail below in conjunction with the accompanying drawings.

In the following description, specific details such as particular system structures, interfaces, techniques, etc., may be presented for the purpose of illustration and not for the purpose of limitation, thereby facilitating a thorough understanding of the present disclosure.

Technical solutions in embodiments of the present disclosure will be described clearly and thoroughly in connection with accompanying drawing of the embodiments of the present disclosure. Obviously, the described embodiments may be only a part of the embodiments, but not all of them. All other embodiments by a person of ordinary skills in the art based on embodiments of the present disclosure without creative efforts should all be within the protection scope of the present disclosure.

The terms “first”, “second”, and “third” in the present disclosure may be only for the purpose of description, and should not be construed as indicating or implying relative importance or implicitly indicating the number of technical features referred to. Therefore, the features preceded by “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure may be only used to explain a motion state, a relative positional relationship between the components in a specific posture (as shown in the drawings). If the specific posture changes, then the directional indication will change accordingly. In addition, the terms “include”, “comprise” and any variations thereof may be intended to cover non-exclusive inclusion. For example, a process, a method, a system, a product, or a device that includes a series of operations or units may be not limited to the listed operations or units, but optionally includes unlisted operations or units, or optionally also includes other operations or units inherent to these processes, methods, products or devices.

Reference to “embodiments” herein means that a specific feature, structure or characteristic described in conjunction with the embodiments may be included in at least one embodiment of the present disclosure. The appearance of this phrase in various locations in the specification does not necessarily refer to the same embodiment, nor may it be an independent or alternative embodiment mutually exclusive with other embodiments. Those skilled in the art may explicitly and implicitly understand that, the embodiments described herein may be combined with other embodiments.

The present disclosure will be described in detail below with reference to the drawings and embodiments.

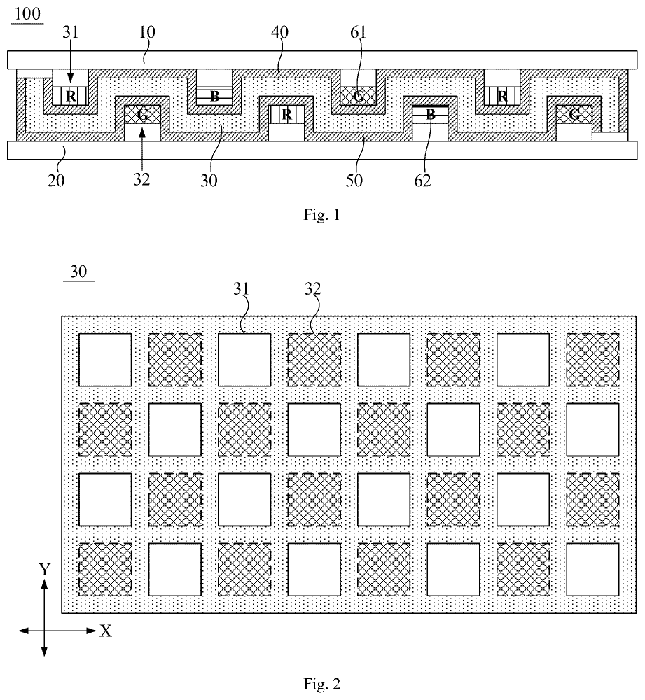

As illustrated in FIG. 1 and FIG. 2, FIG. 1 is a schematic structural diagram of a first embodiment of a display panel according to the present disclosure, FIG. 2 is a schematic planar structural diagram of an embodiment of a light modulation structure according to the present disclosure. In some embodiments, a display panel 100 may be provided. The display panel 100 may include: a first substrate 10; a second substrate 20, arranged opposite to the first substrate 10; a light modulation structure 30, arranged between the first substrate 10 and the second substrate 20, wherein a plurality of first grooves 31 may be defined on a side of the light modulation structure 30 close to the first substrate 10, and a plurality of second grooves 32 may be defined on a side of the light modulation structure 30 close to the second substrate 20, the plurality of first grooves 31 and the plurality of the second grooves 32 may be alternately defined in sequence along each of a first direction X and a second direction Y, the first direction X and the second direction Y may be parallel to the light modulation structure 30 and may intersect with each other; a first electrode 40, arranged on the side of the light modulation structure 30 close to the first substrate 10; a second electrode 50, arranged on the side of the light modulation structure 30 close to the second substrate 20, wherein the second electrode 50 may be configured to form a preset electric field with the first electrode 40 to control a light transmittance of the light modulation structure 30; a plurality of first sub-pixels 61, each arranged within one of the plurality of first grooves 31; and, a plurality of second sub-pixels 62, each arranged within one of the plurality of the second grooves 32.

In some embodiments, the first substrate 10 and the second substrate 20 may each be a transparent carrier plate 11, such as a glass substrate or a flexible transparent substrate, which may be specifically configured according to actual requirements.

In some embodiments, material of the light modulation structure 30 may be an electrochromic material. By defining the first grooves 31 and the second grooves 32 on a front surface and a back surface of the light modulation structure 30 respectively, a continuous semi-enclosed structure on both sides may be formed. The first sub-pixel 61 may be arranged in the first grooves 31, and the second sub-pixel 62 may be arranged in the second grooves 32. A one-to-one correspondence between the sub-pixels on the front surface and the sub-pixels on the back surfaces may be achieved.

In some embodiments, each of the first sub-pixel 61 and the second sub-pixel 62 may include a red sub-pixel, a green sub-pixel, and a blue sub-pixel. Specifically, the first sub-pixel 61 and the second sub-pixel 62 may include a pixel driving circuit and a light-emitting device. The light-emitting device may specifically be a self-luminous device, such as a current-driven self-luminous device like a light-emitting diode (LED), a mini light-emitting diode (Mini-LED), a micro light-emitting diode (Micro-LED), an organic light-emitting diode (OLED), or the like.

In the present embodiment, the plurality of first grooves 31 may be defined on the side of the light modulation structure 30 close to the first substrate 10, and the plurality of second grooves 32 may be defined on the side of the light modulation structure 30 close to the second substrate 20, the plurality of first grooves 31 and the plurality of the second grooves 32 may be alternately defined in sequence along each of the first direction X and the second direction Y. The first direction X and the second direction Y may be parallel to the light modulation structure 30 and the first direction X and the second direction Y may intersect with each other. In this way, the first sub-pixels 61 in the first grooves 31 and the second sub-pixels 62 in the second grooves 32 may be non-overlapping on a plane parallel to the light modulation structure 30, and may be alternately arranged. Therefore, the first sub-pixels 61 and the second sub-pixels 62 may display images independently or cooperatively. By arranging the first electrode 40 on the side of the light modulation structure 30 close to the first substrate 10, and arranging the second electrode 50 on the side of the light modulation structure 30 close to the second substrate 20, the light transmittance of the light modulation structure 30 may be controlled by regulating an electric field between the first electrode 40 and the second electrode 50, thereby switching the light modulation structure 30 between a transparent state and an opaque state. In a case where the light modulation structure 30 is in the transparent state, light from both the first sub-pixels 61 and the second sub-pixels 62 may pass through the light modulation structure 30 and emit towards the first substrate 10 and the second substrate 20. The light modulation structure 30 may have no influence on the viewing angles of the first sub-pixels 61 and the second sub-pixels 62, enabling a double-sided wide-view display. Moreover, switching between high resolution and low resolution may be achieved by controlling the first sub-pixels 61 and/or the second sub-pixels 62 to emit light. In a case where the light modulation structure 30 is in the opaque state and has a light-shielding effect, such that the first sub-pixels 61 may only emit light towards the first substrate 10, and the second sub-pixels 62 may only emit light towards the second substrate 20. The groove structures on the light modulation structure 30 may converge the viewing angles of the first sub-pixels 61, and may converge the viewing angles of the second sub-pixels 62, thereby realizing a narrow-view double-sided display and meeting anti-peeping requirements. Further, by turning off the first sub-pixels 61 or the second sub-pixels 62, a single-sided display may be achieved. In this way, by the single-sided display, not only privacy of displayed content may be enhanced, but also the power consumption may be reduced. Meanwhile, through an arrangement of the light modulation structure 30, requirements to set light modulation layers on both sides of the sub-pixels may be eliminated, a display panel thickness may be reduced. Moreover, since only one light modulation structure 30 may be provided, and only the first electrode 40 and the second electrode 50 may be needed to be arranged on both sides of the light modulation structure 30, control wires may be simplified, and a circuit complexity may be reduced.

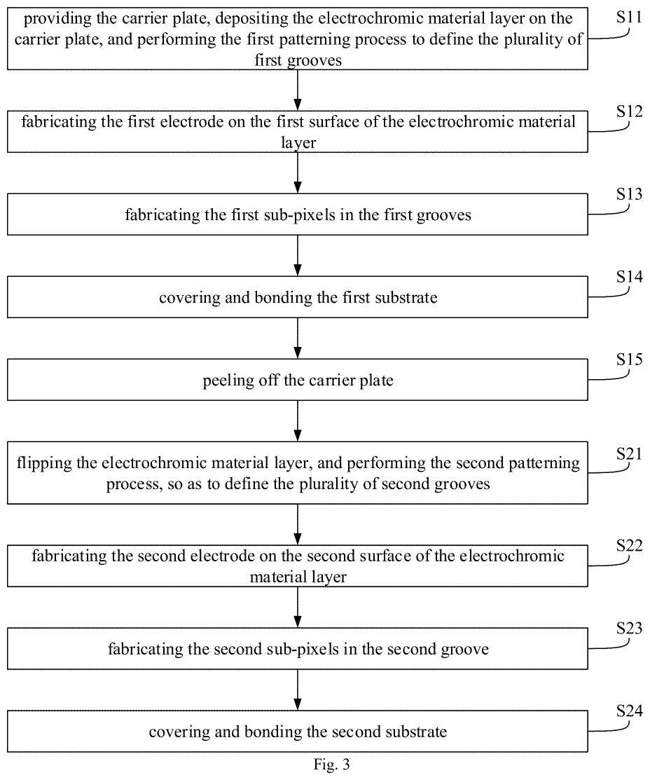

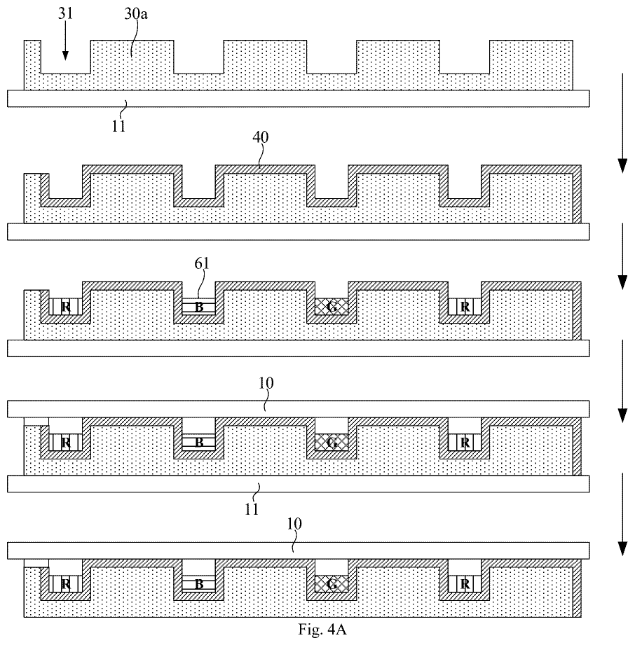

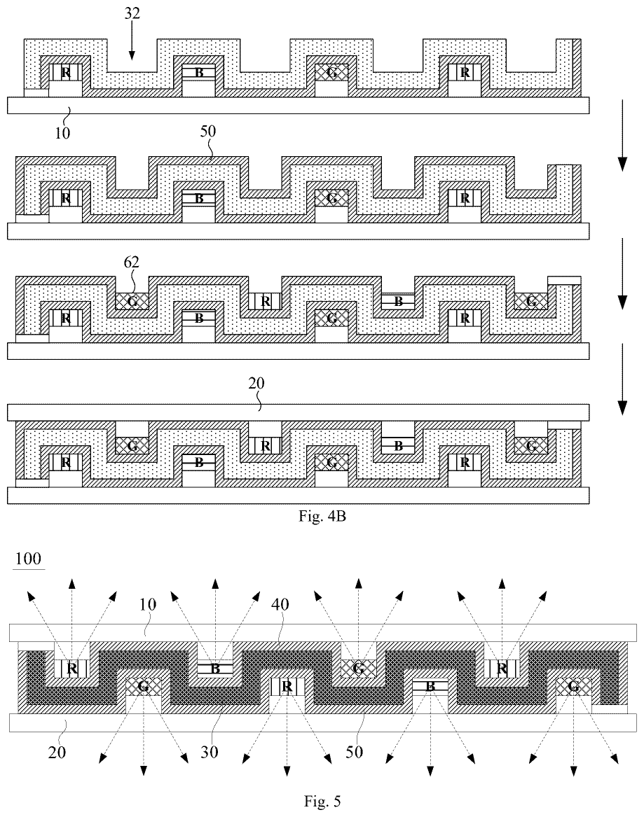

As illustrated in FIG. 3, FIG. 4a, and FIG. 4b, FIG. 3 is a schematic flow chart of an implementation of a preparation method of the display panel 100 according to the present disclosure, FIG. 4a is a schematic process chart matching operations S11 to S15 of FIG. 3, and FIG. 4b is a schematic process chart matching operations S21 to S24 of FIG. 3. Specifically, the preparation method of the above-mentioned display panel 100 may include the following operations at blocks of FIG. 3.

The operation at block S11: providing a carrier plate 11, depositing an electrochromic material layer 30a on the carrier plate 11, and performing a first patterning process to define the plurality of first grooves 31.

The operation at block S12: fabricating the first electrode 40 on a first surface of the electrochromic material layer 30a.

The operation at block S13: fabricating the first sub-pixels 61 in the first grooves 31.

The operation at block S14: covering and bonding the first substrate 10.

The operation at block S15: peeling off the carrier plate 11.

The operation at block S21: flipping the electrochromic material layer 30a, and performing a second patterning process, so as to define the plurality of second grooves 32.

The operation at block S22: fabricating the second electrode 50 on a second surface of the electrochromic material layer 30a.

The operation at block S23: fabricating the second sub-pixels 62 in the second grooves 32.

The operation at block S24: covering and bonding the second substrate 20.

The preparation method provided in the above-mentioned embodiments may be adopted to prepare the display panel 100 in the above-mentioned embodiments. The structure and function of the display panel 100 may be the same as or similar to those of the display panel 100 in the above-mentioned embodiments, and may achieve the same technical effects. For specific details, please refer to the above-mentioned description, which will not be repeated here.

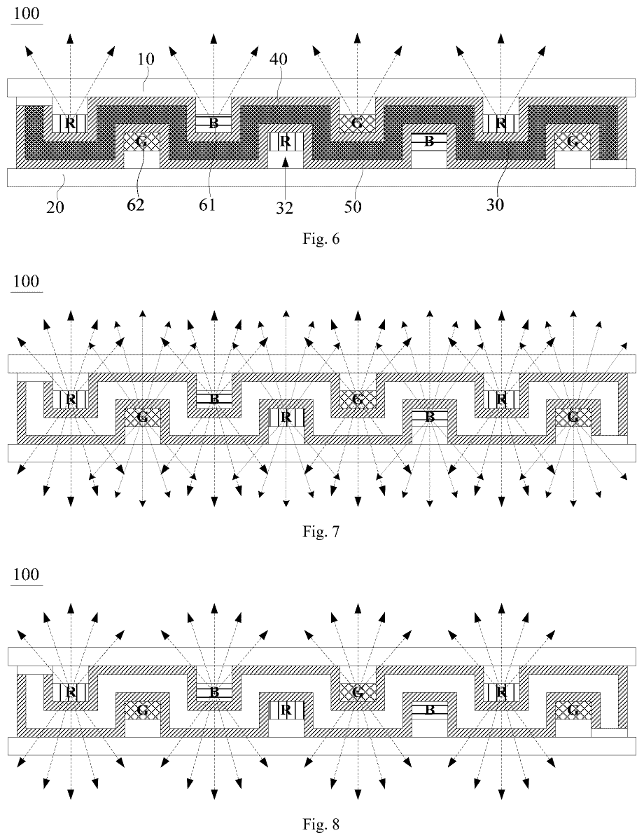

As illustrated in FIGS. 5 and 6, FIG. 5 is a schematic diagram of light emission of the display panel in the embodiment of FIG. 1 in the narrow-view double-sided display mode, and FIG. 6 is a schematic diagram of the light emission of the display panel in the embodiment of FIG. 1 in a narrow-view single-sided display mode. In these figures, dashed arrows diverging outward from the first sub-pixels 61 and/or the second sub-pixels 62 may represent emitted light of the first sub-pixels 61 and/or the second sub-pixels 62. Moreover, the dashed arrows diverging outward from the first sub-pixels 61 and/or the second sub-pixels 62 in the following figures of the present disclosure all represent the emitted light. In some embodiments, when the first electrode 40 and the second electrode 50 form a first preset electric field, the light modulation structure 30 may be opaque, and the display panel 100 may be in a narrow-view display mode. When the first sub-pixels 61 and the second sub-pixels 62 are turned on, the display panel 100 may be in the narrow-view double-sided display mode. When the first sub-pixels 61 or the second sub-pixels 62 are turned on, the display panel 100 may be in the narrow-view single-sided display mode.

Specifically, the voltage of the first electrode 40 and the voltage of the second electrode 50 may be controlled, such that the first electrode 40 and the second electrode 50 may form the first preset electric field, the light modulation structure 30 may be enabled to be switched to the opaque state under the action of the first preset electric field.

As illustrated in FIG. 5, when the light modulation structure 30 is in the opaque state, sidewalls of the first grooves 31 may converge the emitted light of the first sub-pixels 61, to reduce a light-emitting angles of the first sub-pixels 61. The first sub-pixel 61 may display in a narrow view towards the first substrate 10, presenting an anti-peeping effect. That is, the display content may be visible from a front view, but cannot be observed at an angle deviating from the front view. Similarly, the sidewalls of the second grooves 32 may converge the emitted light of the second sub-pixels 62, to reduce the light-emitting angles of the second sub-pixels 62. The second sub-pixel 62 may display in the narrow view towards the second substrate 20, presenting the anti-peeping effect.

In the present display mode, display content on the first substrate 10 side may be determined by the first sub-pixels 61, and the display content on the second substrate 20 side may be determined by the second sub-pixels 62. That is, the display contents on both sides of the display panel 100 may be displayed independently without affecting each other. Meanwhile, both sides of the display panel 100 may be displayed in the narrow view, thereby meeting the privacy requirements.

As illustrated in FIG. 6, when the first sub-pixels 61 are turned on and the second sub-pixels 62 are turned off, the light modulation structure 30 may be in the opaque state and may block the light from the first sub-pixels 61 towards the second substrate 20. Therefore, the first sub-pixels 61 may emit light towards the first substrate 10, and the second sub-pixels 62 may be turned off and do not emit light, so that the display panel 100 may only display on the first substrate 10 side. Similarly, when the second sub-pixels 62 are turned on and the first sub-pixels 61 are turned off, the display panel 100 may only display on the second substrate 20 side.

In this mode, a single-sided small-view display may be performed according to display requirements. For example, if only the first side or only the second side needs to display, the first sub-pixels 61 or the second sub-pixels 62 may be controlled to turn on, which may not only meet the requirements of the single-sided display and the anti-peeping, but also reduce the power consumption.

As illustrated in FIGS. 7 and 8, FIG. 7 is a schematic diagram of light emission of the display panel of the embodiment of FIG. 1 in a wide-view high-resolution display mode, and FIG. 8 is a schematic diagram of light emission of the display panel of the embodiment of FIG. 1 in a wide-view low-resolution display mode. In some embodiments, when the first electrode 40 and the second electrode 50 form a second preset electric field, the light modulation structure 30 may be transparent, and the display panel 100 may be in a wide-view display mode. When the first sub-pixels 61 and the second sub-pixels 62 are turned on, the display panel 100 may be in the wide-view high-resolution display mode. When the first sub-pixels 61 or the second sub-pixels 62 are turned on, the display panel 100 may be in the wide-view low-resolution display mode.

Specifically, the voltage of the first electrode 40 and the voltage of the second electrode 50 may be controlled to make the first electrode 40 and the second electrode 50 form the second preset electric field, so that the light modulation structure 30 may be switched to the transparent state under an action of the second preset electric field. In the transparent state, the light modulation structure 30 does not block or shield the light from the first sub-pixels 61 and the second sub-pixels 62. Therefore, by controlling the light modulation structure 30 to be in the transparent state, the viewing angle of the display panel 100 may be relatively great. When the anti-peeping function is not required, the light modulation structure 30 may be controlled to be in the transparent state.

As illustrated in FIG. 7, when both types of the first sub-pixels 61 and the second sub-pixels 62 are turned on, the first sub-pixels 61 and the second sub-pixels 62 may cooperatively display. That is, the display contents on both sides may be the same, and the display contents may be cooperatively emitted by the first sub-pixels 61 and the second sub-pixels 62, a pixel density may be thus relatively high.

As illustrated in FIG. 8, when the first sub-pixels 61 are turned on and the second sub-pixels 62 are turned off, only the first sub-pixels 61s may perform a double-sided display. The pixel density of an image may be reduced by 50% compared with the embodiment of FIG. 7. Similarly, when the second sub-pixels 62 are turned on and the first sub-pixels 61 are turned off, only the second sub-pixels 62 may perform the double-sided display, and the pixel density of the image may be also reduced by 50% compared with the embodiment of FIG. 7.

In some embodiments, when performing the double-sided wide-view display, switching between the high resolution and the low resolution may be achieved by controlling the first sub-pixels 61 and/or the second sub-pixels 62 to turn on.

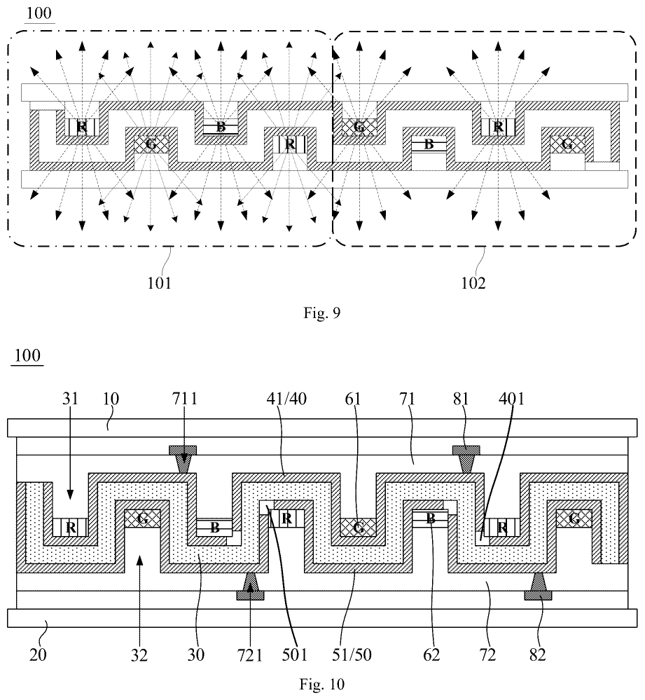

As illustrated in FIG. 9, FIG. 9 is a schematic diagram of the light emission of the display panel in the embodiment of FIG. 1 in a mixed high-and-low resolution display mode. In some embodiments, when the first electrode 40 and the second electrode 50 form the second preset electric field, the light modulation structure 30 may be transparent. The display panel 100 may include a high-resolution display region and a low-resolution display region. In the high-resolution display region, both the first sub-pixels 61 and the second sub-pixels 62 may be turned on. In the low-resolution display region, the first sub-pixels 61 or the second sub-pixels 62 may be turned on. That is, by making a part region of the display panel 100 display in the high-resolution mode and another part region display in the low-resolution mode, a high-quality display may be balanced while reducing the power consumption.

In some embodiments, the light modulation structure 30 may be arranged within the plane, and all functions may be realized only by two control electrodes. The control may be simple, there may be no external screen, the cost may be low, and a narrow-view privacy mode may be additionally realized.

As illustrated in FIG. 10 and FIG. 11, FIG. 10 is a schematic structural diagram of a second embodiment of the display panel according to the present disclosure, and FIG. 11 is a schematic planar structural diagram of an embodiment of the first electrode of FIG. 10. In some embodiments, the first electrode 40 may include a plurality of first sub-electrodes 41. The plurality of first sub-electrodes 41 may be distributed in an array and insulated from each other. A first insulating layer 71 may be further provided between the first electrode 40 and the first substrate 10. The first insulating layer 71 may be further provided with a plurality of first vias 711. A first touch-control connection line 81 may be provided between the first insulating layer 71 and the first substrate 10. The first touch-control connection line 81 may be electrically connected to a matched first sub-electrode 41 through a matched first via 711, and may be configured to transmit a first touch-control signal.

The second electrode 50 may include a plurality of second sub-electrodes 51. The plurality of second sub-electrodes 51 may be distributed in an array and insulated from each other. A second insulating layer 72 may be further provided between the second electrode 50 and the second substrate 20. The second insulating layer 72 may be further provided with a plurality of second vias 721. A second touch-control connection line 82 may be provided between the second insulating layer 72 and the second substrate 20. The second touch-control connection line 82 may be electrically connected to a matched second sub-electrode 51 through a matched second via 721, and may be configured to transmit a second touch-control signal.

A first gap 401 between two adjacent first sub-electrodes 41 may be located at a sidewall of the first groove 31. A second gap 501 between two adjacent second sub-electrodes 51 may be located at a sidewall of the second groove 32. The first gap 401 and the second gap 501 located at two opposite sides of a same sidewall may be arranged in a staggered manner or in a misaligned manner.

By performing a block design on the first electrode 40 and the second electrode 50, and correspondingly connecting the touch-control connection lines with the first sub-electrodes 41 and correspondingly connecting the touch-control connection lines with the second sub-electrodes 51, the first sub-electrodes 41 and the second sub-electrodes 51 may not only serve as control electrodes of the light modulation structure 30, but also serve as touch-control electrodes, so as to realize touch-control functions on both sides of the display panel 100.

By the arrangement where the first gap 401 between two adjacent first sub-electrodes 41 is defined at the sidewall of the first groove 31, the second gap 501 between two adjacent second sub-electrodes 51 is defined at the sidewall of the second groove 32, and the first gap 401 and the second gap 501 located at two opposite sides of a same sidewall are arranged in the staggered manner, a problem that a part of the light modulation structure 30 between a broken seam of the first electrode 40 and a broken seam of the second electrode 50 may have a weakened electric field strength due to the broken seams may be reduced. The weakened electric field strength may cause abnormal state switching response of the light modulation structure 30.

For two adjacent first groove 31 and second groove 32, a side of the first groove 31 and a side of the second groove 32 that are close to each other may share a same sidewall of the light modulation structure 30. By arranging the broken seam of the first electrode 40 and the broken seam of the second electrode 50 on the shared sidewall, it may be beneficial to the electrical connection arrangement between the touch-control connection line and the corresponding first sub-electrode 41 or to the electrical connection arrangement between the touch-control connection line and the second sub-electrodes 51. Further, by arranging the broken seams on two opposite sides of the same sidewall in a staggered manner, it may be ensured that, both sides of a position of the broken seams may form a strong edge electric field with a complete electrode on the opposite side, and a normal response of the transparent state of the light modulation structure 30 may still be guaranteed.

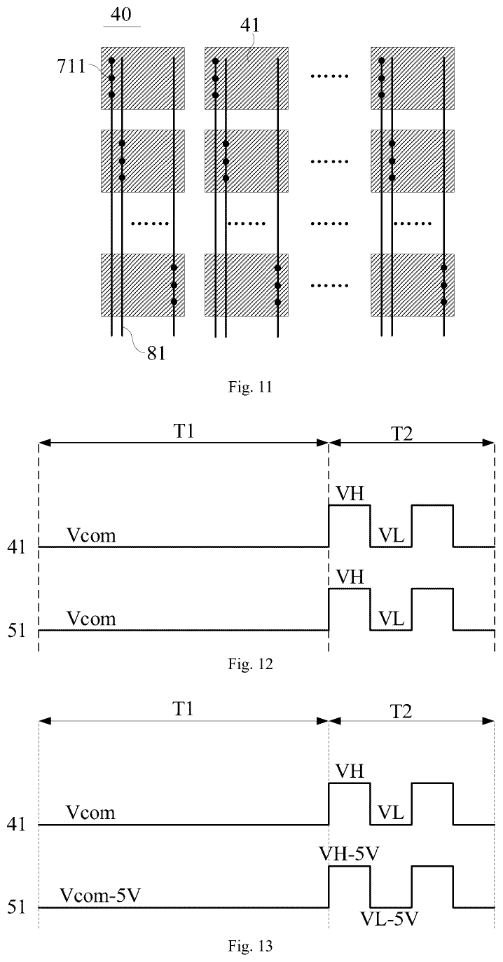

As illustrated in FIG. 12 and FIG. 13, FIG. 12 is a control timing diagram of the first electrode and the second electrode in an embodiment of the present disclosure, and FIG. 13 is a control timing diagram of the first electrode and the second electrode in another embodiment of the present disclosure. In some embodiments, when the display panel 100 performs display work, the display panel 100 may sequentially display images frame by frame. Specifically, each image frame may include a display phase T1 and a touch-control phase T2.

In the display phase T1, the first sub-electrode 41 may serve as a cathode of the first sub-pixel 61, and may be configured to transmit a first cathode signal; the second sub-electrode 51 may further serve as a cathode of the second sub-pixel 62, and may be configured to transmit a second cathode signal. A first difference or a second difference may be maintained between the first cathode signal and the second cathode signal. One of the first difference and the second difference may be configured to maintain the transparent state of the light modulation structure 30, or another of the first difference and the second difference may be configured to maintain the opaque state of the light modulation structure 30.

In the touch-control phase T2, the first sub-electrode 41 may serve as a first touch-control electrode, and may be configured to transmit the first touch-control signal, the second sub-electrode 51 may serve as a second touch-control electrode and may be configured to transmit the second touch-control signal. The first difference or the second difference may be maintained between the first touch-control signal and the second touch-control signal. One of the first difference and the second difference may be configured to maintain the transparent state of the light modulation structure 30, or another of the first difference and the second difference may be configured to maintain the opaque state of the light modulation structure 30.

In some embodiments, an example may be described, in which: when the voltage difference between the first electrode 40 and the second electrode 50 is 0V, the second preset electric field is formed, and the light modulation structure 30 is in the transparent state under the action of the second preset electric field; and, when the voltage difference between the first electrode 40 and the second electrode 50 is 5V, the first preset electric field is formed, and the light modulation structure 30 is in the opaque state under the action of the first preset electric field.

As illustrated in FIG. 12, in the present embodiment, in each image frame, the voltage difference between the first sub-electrode 41 and the second sub-electrode 51 may be 0V, the light modulation structure 30 may be in the transparent state, and the display panel 100 may be in the double-sided wide-view display mode. That is, at any moment in a frame, the voltage difference between the first sub-electrode 41 and the second sub-electrode 51 may be 0V. Specifically, in the display phase T1, the first sub-electrode 41 may serve as the cathode of the first sub-pixel 61, and the second sub-electrode 51 may serve as the cathode of the second sub-pixel 62, the first sub-electrode 41 and the second sub-electrode 51 may be configured to transmit cathode signals, and the cathode voltages on both the first sub-electrode 41 and the second sub-electrode 51 may remain unchanged. In the touch-control phase T2, the first sub-electrode 41 may serve as the first touch-control electrode and may be configured to transmit the first touch-control signal, the second sub-electrode 51 may serve as the second touch-control electrode and may be configured to transmit the second touch-control signal, thereby realizing the touch-control functions on both sides of the display panel 100. Meanwhile, to maintain the light modulation structure 30 in the transparent state, the voltage difference between the first touch-control signal and the second touch-control signal may be maintained at 0V. That is, at any moment in the touch-control phase T2, the voltage difference between the first touch-control signal and the second touch-control signal may be 0V, so as to maintain the state of the light modulation structure 30 unchanged while realizing the touch-control function.

As illustrated in FIG. 13, in the present embodiment, in each image frame, the voltage difference between the first sub-electrode 41 and the second sub-electrode 51 may be 5V, the light modulation structure 30 may be in the opaque state, and the display panel 100 may be in the narrow-view display mode. In the display phase T1, the first sub-electrode 41 may serve as the cathode of the first sub-pixel 61, the second sub-electrode 51 may serve as the cathode of the second sub-pixel 62, and the first sub-electrode 41 and the second sub-electrode 51 may be configured to transmit cathode signals. To maintain the light modulation structure 30 in the opaque state, the voltage difference between the first sub-electrode 41 and the second sub-electrode 51 may need to be maintained at 5V. Therefore, if the cathode signal of the first sub-electrode 41 being Vcom is taken as a baseline, the cathode signal of the second sub-electrode 51 may be (Vcom−5V). Correspondingly, in the touch-control phase T2, a high level of the first touch-control signal of the first sub-electrode 41 may be VH, and a low level of the first touch-control signal of the first sub-electrode 41 may be VL. Thus, a high level of the second touch-control signal of the second sub-electrode 51 may be (VH−5V), and a low level of the second touch-control signal of the second sub-electrode 51 may be (VL−5V). The state of the light modulation structure 30 may remain unchanged, while the touch-control function may be realized. In some embodiments, considering a limit range of the driving IC voltage, the cathode signal of the first sub-electrode 41 may also be set to (Vcom+2.5V), and the cathode signal of the second sub-electrode 51 may be set to (Vcom−2.5V).

In the above-mentioned embodiments, when the display panel 100 is in the wide-view display mode, since the light modulation structure 30 is transparent, the display contents on both sides may have a mirror effect. That is, when a normal image is viewed on the first substrate 10 side, a mirrored image of the image may be viewed on the second substrate 20 side, which may affect the user experience, especially for a displayed text content. Therefore, further, when taking a user A as a main subject, a switching control may be performed according to a position where the user A is located, to ensure that the image viewed by the main subject personnel may be normal. In some embodiments, since touch-control electrodes are provided on both sides, the user may perform the switching control through the touch-control function.

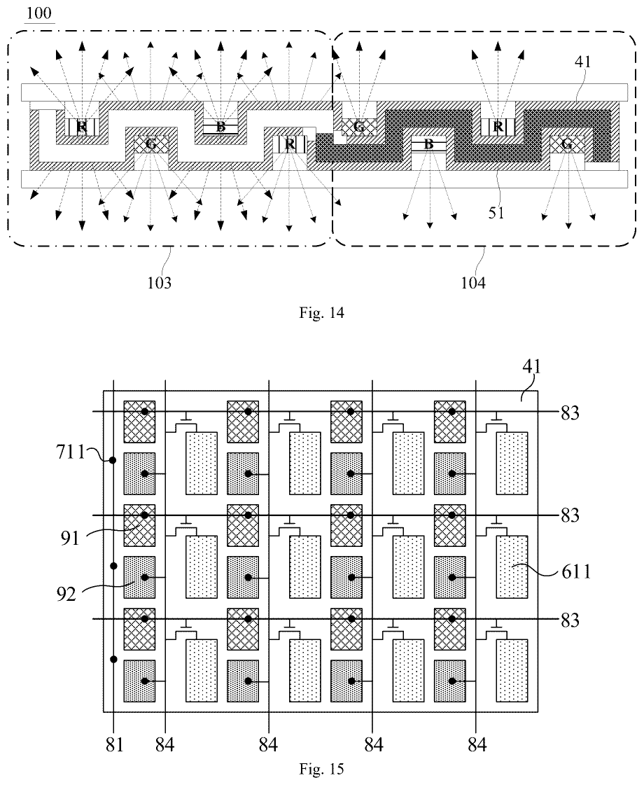

As illustrated in FIG. 14, FIG. 14 is a light emission state diagram of a display mode of the display panel in FIG. 10. Further, for display contents of mixed images and text, the following settings may be made: for a part of the light modulation structure 30 matching with an image region 103, the second preset electric field may be controlled as between the first sub-electrode 41 and the second sub-electrode 51 in the image region 103, so that the light modulation structure 30 in the image region 103 may be in the transparent state, thereby realizing high-resolution image display. For a part of the light modulation structure 30 matching with a text region 104, the first preset electric field may be controlled as between the first sub-electrode 41 and the second sub-electrode 51 in the text region 104, so that the light modulation structure 30 in the text region 104 may be in the opaque state, the first sub-pixels 61 may display matched text content towards the first substrate 10, and the second sub-pixels 62 may display matched text content towards the second substrate 20. The first sub-pixels 61 and the second sub-pixels 62 may display independently, thereby realizing a non-mirror text display on both sides. This display mode may not only maintain a fineness of the image, but also solve the problem of text mirror.

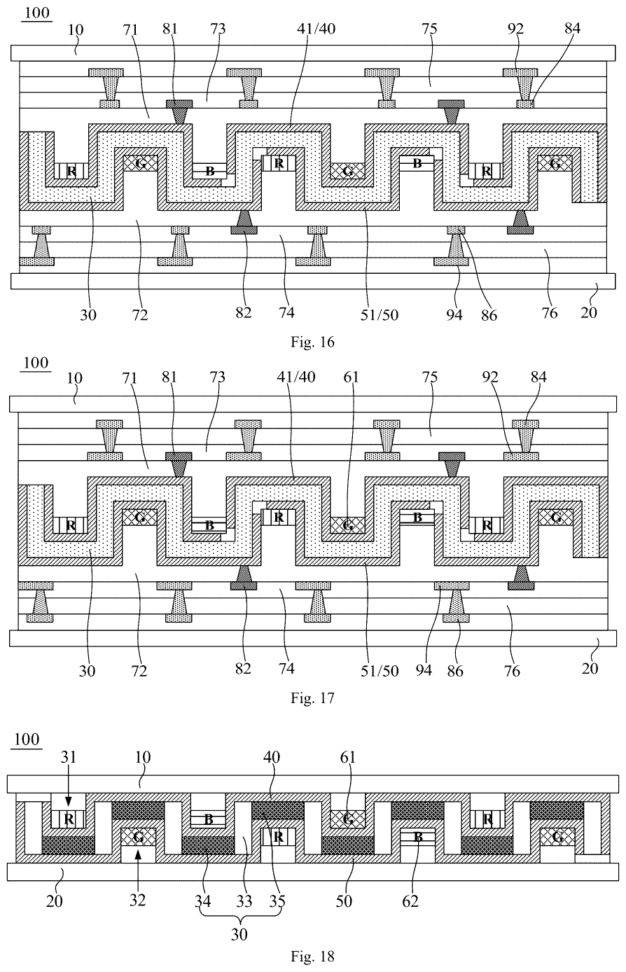

As illustrated in FIG. 15-FIG. 17, FIG. 15 is a schematic diagram of a planar positional relationship of various electrodes of a third embodiment of the display panel according to the present disclosure, FIG. 16 is a schematic structural diagram of a third embodiment of the display panel according to the present disclosure, and FIG. 17 is a schematic structural diagram of a fourth embodiment of another display panel according to the present disclosure. In some embodiments, the first insulating layer 71, one or more first scan touch-control electrodes 91, one or more first data touch-control electrodes 92, a third insulating layer 73, a first scan line 83, a fifth insulating layer 75, and a first data line 84 may be sequentially stacked on the side of the first electrode 40 close to the first substrate 10. The first scan touch-control electrodes 91 and the first data touch-control electrodes 92 may be distributed in an array. The first scan touch-control electrodes 91 may be insulated from the first data touch-control electrodes 92. The first scan touch-control electrodes 91 in a same row may be connected to a same first scan line 83. The first data touch-control electrodes 92 in a same column may be connected to a same first data line 84. The second insulating layer 72, one or more second scan touch-control electrodes, one or more second data touch-control electrodes 94, a fourth insulating layer 74, a second scan line, a sixth insulating layer 76, and a second data line 86 may be sequentially stacked on a side of the second electrode 50 close to the second substrate 20. The second scan touch-control electrodes and the second data touch-control electrodes 94 may be distributed in an array. The second scan touch-control electrodes may be insulated from the second data touch-control electrodes 94. The second scan touch-control electrodes in a same row may be connected to a same second scan line The second data touch-control electrodes 94 in a same column may be connected to a same second data line 86.

The first scan touch-control electrode 91 and the first data touch-control electrode 92 may be arranged on a part of the light modulation structure 30 between two adjacent first grooves 31. The first scan touch-control electrode 91 and the first data touch-control electrode 92 may be misaligned from the first touch-control connection line 81. Specifically, the first touch-control connection line 81 may be arranged close to one of the two adjacent first grooves 31. The first scan touch-control electrode 91 and the second data touch-control electrode 94 may be arranged close to another of the two adjacent first grooves 31. These touch-control structures may be all arranged on sidewalls between the first groove 31 and the second groove 32 that are adjacent to each other, thereby reducing influences of the first touch-control connection line 81, the first scan line, and the first data line 84 on the image display. Similarly, the second scan touch-control electrode, the second data touch-control electrode 94, the second touch-control connection line 82, the second scan line, and the second data line 86 may be also arranged in this way.

Specifically, the first scan touch-control electrode 91 and the first data touch-control electrode 92 may be pixel-level electrodes and may both be transparent electrodes. The specific materials may be transparent conductive materials, such as indium tin oxide (ITO), indium zinc oxide (IZO), indium gallium zinc oxide (IGZO), or other transparent conductive materials. The first scan touch-control electrode 91 may be separated from the first sub-electrode 41 by an insulating layer. The first data touch-control electrode 92 may be separated from the first sub-electrode 41 by an insulating layer. The first scan touch-control electrode 91 may be electrically connected to the first scan line 83 through a connection via. The first data touch-control electrode 92 may be electrically connected to the first data line 84 through a connection via. Similarly, the second scan touch-control electrode, the second data touch-control electrode 94, the second touch-control connection line 82, the second scan line, and the second data line 86 may also be arranged in this way.

As illustrated in FIG. 16, in the present embodiment, routing of the scan lines and data lines may be performed first, and then manufacturing procedures of the scan touch-control electrodes and data touch-control electrodes may be performed. In this way, the scan lines or data lines on the same display side may share a mask with the touch-control connection lines, and the scan touch-control electrodes and data touch-control electrodes on the same display side may share a mask.

As illustrated in FIG. 17, in the present embodiment, the manufacturing procedures of the scan touch-control electrodes and data touch-control electrodes may also be performed first, and then the routing of the scan lines and data lines may be performed. In this way, the scan touch-control electrodes, data touch-control electrodes, and touch-control connection lines on the same display side may share a mask.

Through the above-mentioned settings, time duration of a frame may be divided into the display phase T1 and the touch-control phase T2 by time-division multiplexing of the scan lines and data lines. In the display phase T1, the scan lines may be configured to normally transmit scan signals, and the data lines may be configured to normally transmit data signals, thereby driving the sub-pixels to normally display corresponding images. In the touch-control phase T2, the scan lines may be multiplexed as horizontal touch-control lines, the horizontal touch-control lines may be configured to transmit low-voltage pulses to the scan touch-control electrodes for induction detection, to complete row positioning of a touch-control position; and, the data lines may be multiplexed as vertical touch-control lines, the vertical touch-control lines may be configured to transmit pulse square waves to the data touch-control electrodes for induction detection, to complete column positioning of the touch-control position. Through the row positioning and the column positioning, a point coordinates of a precise touch-control position may be obtained, thereby realizing pixel-level precise touch control. This precise touch-control mode may be applicable to scenarios such as precise drawing and high-precision touch-control demand operations.

In the touch-control phase T2, when the scan lines transmit low-voltage pulses, a gate-drain voltage Vgd of the driving transistor may need to be controlled to be lower than a threshold voltage of the driving transistor, so that the driving transistor may be in a cut-off state to avoid image anomalies. At the same time, in the touch-control phase T2, the first electrode 40 and the second electrode 50 may only need to maintain a normal output of the cathode signal, and there may be no special waveform requirement.

In some embodiments, the first scan line 83, the first data line 84, the first scan touch-control electrode 91, the first data touch-control electrode 92, the second scan line, the second data line 86, the second scan touch-control electrode, and the second data touch-control electrode 94 mentioned above may be all arranged on sidewalls between adjacent first grooves 31 and second grooves 32. In this way, the above-mentioned touch-control structures may not completely cover the first sub-electrode 41 and the second sub-electrode 51, so that the first sub-electrode 41 and the second sub-electrode 51 may still maintain well touch-control induction. When the display panel 100 does not need high-precision touch, the first sub-electrode 41 and the second sub-electrode 51 may be switched for touch-control induction, to reduce the power consumption.

In the display panel 100 of the above-mentioned embodiments, in order to realize that the first sub-pixels 61 and the second sub-pixels 62, when cooperatively display images, support independent display of images and maintain high-resolution display, the first sub-pixels 61 and the second sub-pixels 62, whose projections on the front and back surfaces are adjacent to each other, may be set as sub-pixels of different colors. Cycle units may be ensured, to avoid a case, in which the sub-pixels, whose projections on the front and back sides are adjacent to each other, have a same color.

In other words, pixel arrangement rules of the first sub-pixels 61 and the second sub-pixels 62 may need to meet the following three conditions from the first to the third.

First, when the first sub-pixels 61 and the second sub-pixels 62 cooperatively participate in the double-sided display image, the first sub-pixels 61 and the second sub-pixels 62 may cooperatively form sub-pixels of the image. That is, any type of the first sub-pixels 61 and the second sub-pixels 62 may emit light to participate in the display work. The first sub-pixels 61 and the second sub-pixels 62 may need to form a plurality of array-distributed cycle units. Each cycle unit may at least include the red sub-pixel, the green sub-pixel, and the blue sub-pixel.

Second, when only the first sub-pixels 61 participate in the image display, the first sub-pixels 61 may form the sub-pixels of the image. That is, only the first sub-pixels 61 may emit light to participate in the display work, and the second sub-pixels 62 may be turned off. The arrangement of the first sub-pixels 61 may form the plurality of array-distributed cycle units. Each cycle unit may at least include the red sub-pixel, the green sub-pixel, and the blue sub-pixel.

Third, when only the second sub-pixels 62 participate in the image display, the second sub-pixels 62 may form the sub-pixels of the image. That is, only the second sub-pixels 62 may emit light to participate in the display work, and the first sub-pixels 61 may be turned off. The arrangement of the second sub-pixels 62 may form the plurality of array-distributed cycle units. Each cycle unit may at least include the red sub-pixel, the green sub-pixel, and the blue sub-pixel.

As illustrated in FIG. 1, for example, the cycle unit of the first sub-pixels 61 may be RGB, and the cycle unit of the second sub-pixels 62 may be BRG. At this time, the projection of the first sub-pixels 61 and the second sub-pixels 62 on the light modulation structure 30 may be RBGRBG, which may not only realize high-resolution double-sided display but also ensure normal the single-sided display. R may represent the red sub-pixel, G may represent the green sub-pixel, and B may represent the blue sub-pixel. In some other embodiments, an arrangement manner of the first sub-pixels 61 and the second sub-pixels 62 may also be in other ways, as long as the above-mentioned conditions may be met, which may be not listed here one by one.

As illustrated in FIG. 18, FIG. 18 is a schematic structural diagram of a fifth embodiment of the display panel according to the present disclosure. In some embodiments, the light modulation structure 30 may include a first light modulation layer 33, a second light modulation layer 34, and a third light modulation layer 35. A sidewall at a side, where two adjacent first groove 31 and second groove 32 are close to each other, may be the first light modulation layer 33. A bottom wall of the first groove 31 close to the second substrate 20 may be the second light modulation layer 34. A bottom wall of the second groove 32 close to the first substrate 10 may be the third light modulation layer 35. The light modulation structure 30 may include the opaque state and the transparent state. Under the action of a same preset electric field, the transparent state of the second light modulation layer 34 may be reverse to that of the first light modulation layer 33, and the transparent state of the third light modulation layer 35 may be reverse to that of the first light modulation layer 33.

In some embodiments, a part of the light modulation structure 30 of the sidewall structure between adjacent sub-pixels may be the first light modulation layer 33. A part of the light modulation structure 30 matching with the side of the first sub-pixel 61 close to the second substrate 20 may be the second light modulation layer 34. A part of the light modulation structure 30 matching with the side of the second sub-pixel 62 close to the first substrate 10 may be the third light modulation layer 35. The electrical requirement of the first light modulation layer 33 may be opposite or reverse to that of the second light modulation layer 34, and the electrical requirement of the first light modulation layer 33 may also be opposite or reverse to that of the third light modulation layer 35. The electrical requirement of the second light modulation layer 34 may be the same as that of the third light modulation layer 35. That is, under the action of the same electric field: the first light modulation layer 33 may be in the transparent state, while the second light modulation layer 34 and the third light modulation layer 35 may be both in the opaque state. Alternatively, under the action of the same electric field: the first light modulation layer 33 may be in the opaque state, while the second light modulation layer 34 and the third light modulation layer 35 may be both in the transparent state.

Specifically, the display panel 100 may be prepared through the following embodiments, and for details as described in the following.

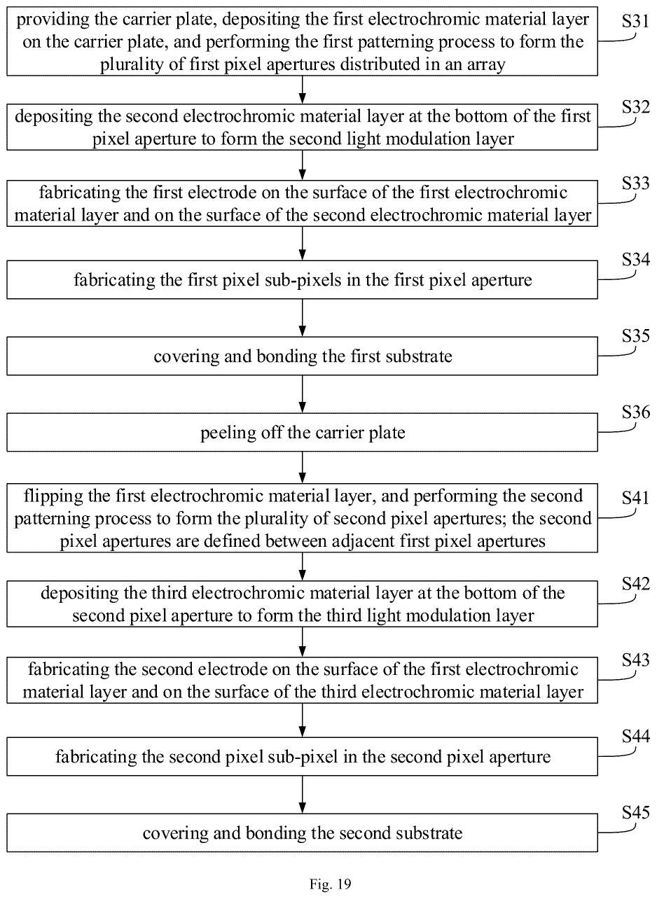

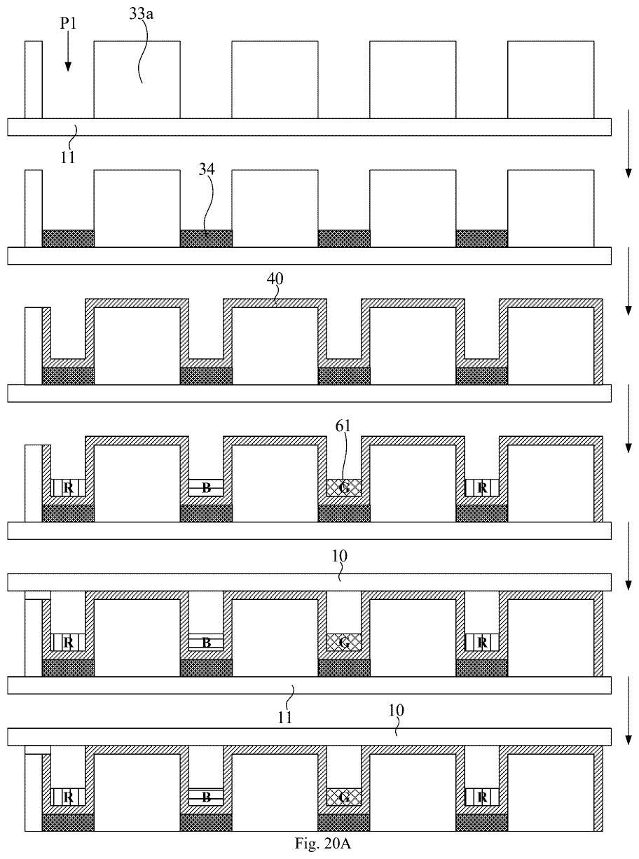

As illustrated in FIG. 19, FIG. 20a, and FIG. 20b, FIG. 19 is a schematic flow chart of another embodiment of a preparation method of the display panel 100 according to the present disclosure, FIG. 20a is a schematic process chart matching operations S31 to S36 of FIG. 19, and FIG. 20b is a schematic process chart matching operations S41 to S45 of FIG. 19. Specifically, the preparation method of the above-mentioned display panel 100 may include the operations as illustrated at blocks of FIG. 19.

The operation at block S31: providing the carrier plate 11, depositing a first electrochromic material layer 33a on the carrier plate 11, and performing the first patterning process to form a plurality of first pixel apertures P1 distributed in an array.

The operation at block S32: depositing a second electrochromic material layer at a bottom of the first pixel aperture P1 to form a second light modulation layer.

The operation at block S33: fabricating the first electrode 40 on a surface of the first electrochromic material layer 33a and on a surface of the second electrochromic material layer.

The operation at block S34: fabricating a first pixel sub-pixel 61 in the first pixel aperture P1.

The operation at block S35: covering and bonding the first substrate 10.

The operation at block S36: peeling off the carrier plate 11.

The operation at block S41: flipping the first electrochromic material layer 33a, and performing the second patterning process to form a plurality of second pixel apertures P2, wherein a plurality of second pixel apertures P2 may be defined between adjacent first pixel apertures P1.

The operation at block S42: depositing a third electrochromic material layer at a bottom of the second pixel aperture P2 to form a third light modulation layer.

The operation at block S43: fabricating the second electrode 50 on a surface of the first electrochromic material layer 33a and on a surface of the third electrochromic material layer.

The operation at block S44: fabricating a second pixel sub-pixel 62 in the second pixel aperture P2.

The operation at block S45: covering and bonding the second substrate 20.

Specifically, the first pixel aperture P1 may match with the first groove 31 structure of the display panel 100 in the above-mentioned embodiments. The second pixel aperture P2 may match with the second groove 32 structure of the display panel 100 in the above-mentioned embodiments. The first electrochromic material layer 33a may form the first light modulation layer in the above-mentioned embodiments after two patterning processes. The first light modulation layer, the second light modulation layer, and the third light modulation layer may together form the light modulation structure 30.

In the display panel 100 prepared by the present embodiment, the light modulation structure 30 may include the first light modulation layer with reverse electrical requirement to that of the second light modulation layer and to that of the third light modulation layer. The states of the first light modulation layer, the second light modulation layer, and the third light modulation layer may be controlled by regulating the electric field between the first electrode 40 and the second electrode 50 through controlling the voltage of the first electrode 40 and the voltage of the second electrode 50.

For example, when the first preset electric field is formed between the first electrode 40 and the second electrode 50, the first light modulation layer may be in the opaque state, and the second light modulation layer and the third light modulation layer may be in the transparent state. At this time, the first light modulation layer may converge the viewing angles of the first sub-pixels 61 and the second sub-pixels 62, thereby realizing a narrow-view display to meet the anti-peeping requirements of the display panel 100. When the second preset electric field is formed between the first electrode 40 and the second electrode 50, the first light modulation layer may be in the transparent state, and the second light modulation layer and the third light modulation layer may be in the opaque state. The display panel 100 may realize a wide-view display, and may realize the double-sided display or the single-sided display.

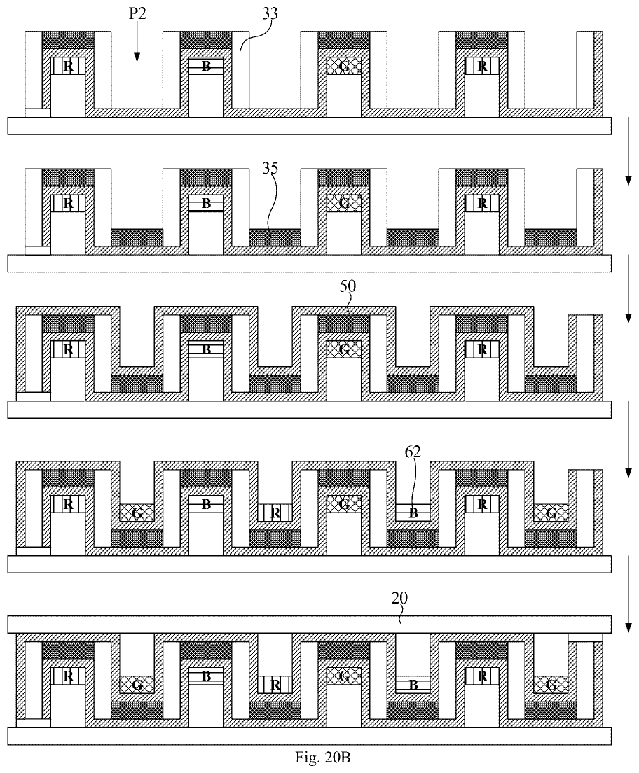

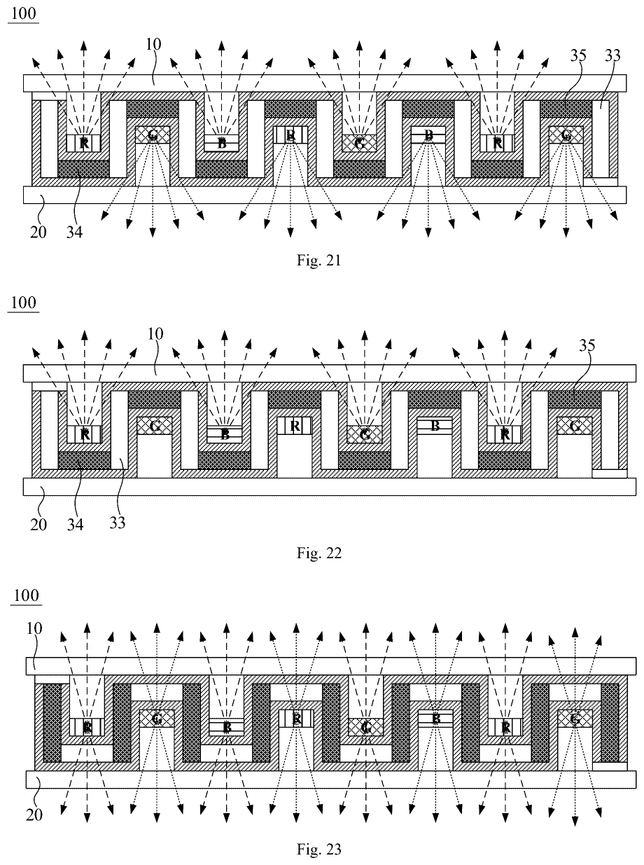

As illustrated in FIGS. 21 and 22, FIG. 21 is a schematic diagram of light emission of the display panel in the embodiment of FIG. 18 in the wide-view double-sided display mode, and FIG. 22 is a schematic diagram of light emission of the display panel in the embodiment of FIG. 18 in the wide-view single-sided display mode. In some embodiments, when the second preset electric field is formed between the first electrode 40 and the second electrode 50, the first light modulation layer may be in the transparent state, while the second light modulation layer and the third light modulation layer may be in the opaque state, the display panel 100 may be in a first wide-view display mode.

Specifically, the voltage of the first electrode 40 and the voltage of the second electrode 50 may be controlled to form the second preset electric field between the first electrode 40 and the second electrode 50. For example, by controlling the voltage of the first electrode 40 and the voltage of the second electrode 50, the voltage difference between the first electrode 40 and the second electrode 50 may be 0V, thereby forming the second preset electric field. At this time, the first light modulation layer may be in the transparent state, while the second light modulation layer and the third light modulation layer may be in the opaque state. In this state, the first light modulation layer may be transparent and may not converge the viewing angle of the sub-pixels, and the display panel 100 may displays in the wide view. The second light modulation layer may be opaque. The second light modulation layer may be located on the side of the first sub-pixel 61 close to the second substrate 20, which may block the light emitted by the first sub-pixels 61 towards the second substrate 20, so that the first sub-pixels 61 may only display an image towards the first substrate 10. The third light modulation layer may be opaque. The third light modulation layer may be located on the side of the second sub-pixels 62 close to the first substrate 10, which may block the light emitted by the second sub-pixels 62 towards the first substrate 10, so that the second sub-pixels 62 may only display an image towards the second substrate 20.

As illustrated in FIG. 21, in the present embodiment, both the first sub-pixels 61 and the second sub-pixels 62 may be turned on. The first sub-pixels 61 may display towards the first substrate 10. The second sub-pixels 62 may display towards the second substrate 20. The first sub-pixels 61 and the second sub-pixels 62 may display independently. That is, the first sub-pixels 61 may display a first image, and the second sub-pixels 62 may display a second image. The first image and the second image may be the same or different. In this way, both sides of the display panel 100 may display the same image or different images to meet different usage scenarios.

As illustrated in FIG. 22, in the present embodiment, the first sub-pixels 61 may be turned on, and the second sub-pixels 62 may be turned off. The first sub-pixels 61 may display an image towards the first substrate 10, so that the display panel 100 may only display on the first substrate 10 side, thereby realizing the single-sided display. Similarly, when the second sub-pixels 62 is turned on and the first sub-pixels 61 is turned off, the second sub-pixels 62 may display an image towards the second substrate 20, so that the display panel 100 may only display on the second substrate 20 side, thereby realizing the single-sided display. Specifically, the display surface may be switched according to display requirements, so that the display panel 100 may realize one-key switching of the display surface according to user requirements.

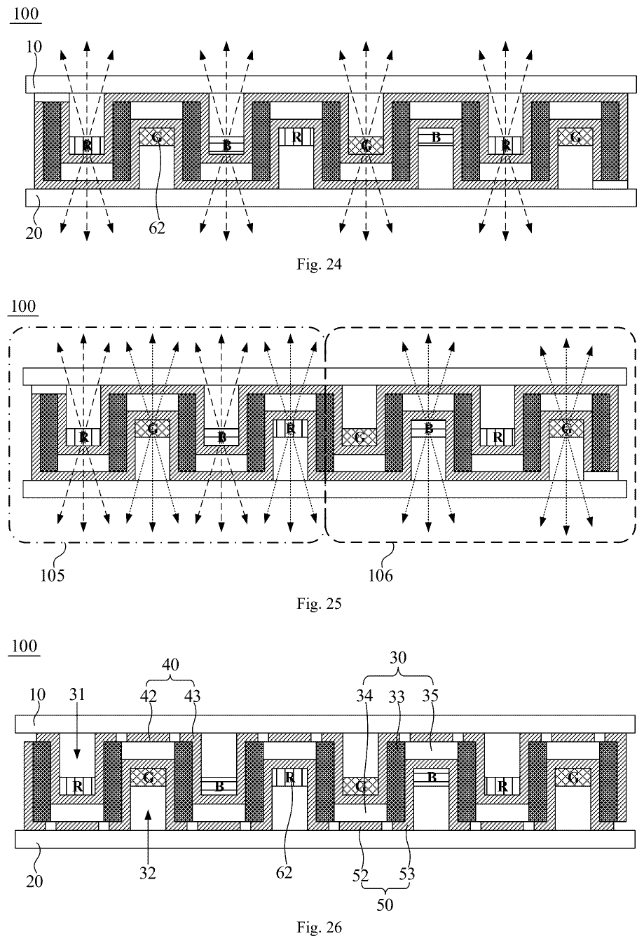

As illustrated in FIGS. 23 and 24, FIG. 23 is a schematic diagram of the light emission of the display panel in the embodiment of FIG. 18 in a first narrow-view double-sided display mode, and FIG. 24 is another schematic diagram of light emission of the display panel in the embodiment of FIG. 18 in the first narrow-view double-sided display mode. In some embodiments, when the first electrode 40 and the second electrode 50 form the first preset electric field, the first light modulation layer may be in the opaque state, while the second light modulation layer and the third light modulation layer may be in the transparent state, and the display panel 100 may be in a first narrow-view display mode.

Specifically, the voltage of the first electrode 40 and the voltage of the second electrode 50 may be controlled to form the first preset electric field between the first electrode 40 and the second electrode 50. For example, by controlling the voltage of the first electrode 40 and the voltage of the second electrode 50, the voltage difference between the first electrode 40 and the second electrode 50 may be 5V, thereby forming the first preset electric field. At this time, the first light modulation layer may be in the opaque state, while the second light modulation layer and the third light modulation layer may be in the transparent state. In this state, the first light modulation layer may be opaque and block the light emitted by the sub-pixels, thereby reducing light-emitting angles of the first sub-pixels 61 and the second sub-pixels 62. The second light modulation layer and the third light modulation layer may be transparent, so that the first sub-pixels 61 and the second sub-pixels 62 may emit light towards both sides. In this way, the display viewing angles of the display panel 100 on the first substrate 10 side and on the second substrate 20 side may all be reduced. The anti-peeping requirements of the double-sided display may thus be met.

As illustrated in FIG. 23, in the present embodiment, both the first sub-pixels 61 and the second sub-pixels 62 may be turned on to participate in the image display. The display panel 100 may display images on both the first substrate 10 and the second substrate 20, thereby realizing a double-sided narrow-view high-resolution display. In scenarios with high resolution requirements and anti-peeping requirements, the display panel 100 may be switched to this display mode for display work.

As illustrated in FIG. 24, in the present embodiment, only the first sub-pixels 61 may be turned on, and the second sub-pixels 62 may be turned off. At this time, only the first sub-pixels 61 may participate in the image display. The display panel 100 may display images on both the first substrate 10 and the second substrate 20, thereby realizing a double-sided narrow-view low-resolution display. In scenarios with low resolution requirements and anti-peeping requirements, the display panel 100 may be switched to the present display mode for the display work. In a case where high resolution is not required, by switching the display panel 100 to low-resolution display, since the second sub-pixels 62 are turned off, the power consumption may be effectively reduced. In some embodiments, depending on display requirements or display characteristics of the first sub-pixels 61 and the second sub-pixels 62, the first sub-pixels 61 may be turned on and the second sub-pixels 62 may be turned off, or the first sub-pixels 61 may be turned off and the second sub-pixels 62 may be turned on. Alternatively, switching may be performed according to specific situation.

As illustrated in FIG. 25, FIG. 25 is another schematic diagram of light emission of the display panel 100 in the embodiment of FIG. 18 in the first narrow-view double-sided display mode. In the present embodiment, according to characteristics of the image needed to be displayed, the display surface of the display panel 100 may be partitioned into a high-resolution region 105 and a low-resolution region 106. An area in the image that requires high-resolution display may match with the high-resolution region 105, and an area that does not require high-resolution display may match with the low-resolution region 106. When displaying, both the first sub-pixels 61 and the second sub-pixels 62 in the high-resolution region 105 may be turned on to participate in the image display; and, in the low-resolution region 106, only one type of the first sub-pixels 61 or the second sub-pixels 62 may be turned on to participate in the image display. By adopting the present display manner for the mixed high-and-low resolution display, the image display quality may be maintained while reducing the power consumption.

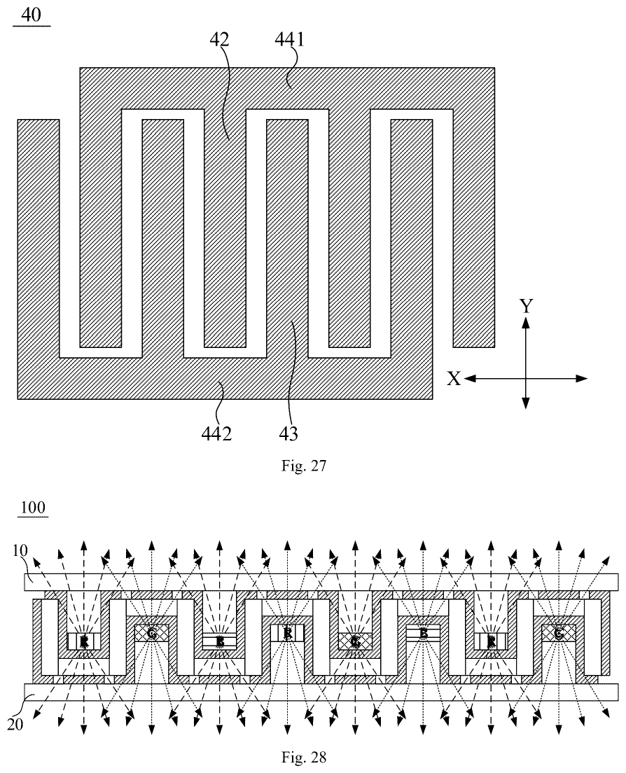

As illustrated in FIG. 26 and FIG. 27, FIG. 26 is a schematic structural diagram of a sixth embodiment of the display panel according to the present disclosure, and FIG. 27 is a schematic planar structural diagram of the first electrode of FIG. 26. In some embodiments, the first electrode 40 may include a third sub-electrode 42 and a fourth sub-electrode 43. The third sub-electrode 42 may be insulated from the fourth sub-electrode 43. The third sub-electrode 42 may be arranged on a side surface of the third light modulation layer close to the first substrate 10. The fourth sub-electrode 43 may be arranged on a groove wall surface of a first groove 31 and on a side surface of the first light modulation layer close to the first substrate 10, wherein the first light modulation layer may be adjacent to the first groove 31. The second electrode 50 may include a fifth sub-electrode 52 and a sixth sub-electrode 53 that are insulated from each other. The fifth sub-electrode 52 may be arranged on a side surface of the second light modulation layer close to the second substrate 20. The sixth sub-electrode 53 may be arranged on a groove wall surface of a second groove 32 and on a side surface of the first light modulation layer close to the second substrate 20, wherein the first light modulation layer may be adjacent to the second groove 32.

In some embodiments, ends of the third sub-electrodes 42 on a same side may be electrically connected through a first connection portion 441. Ends of the fourth sub-electrodes 43 on a same side may be electrically connected through a second connection portion 442. Ends of the fifth sub-electrodes 52 on a same side may be electrically connected through a third connection portion. Ends of the sixth sub-electrodes 53 on a same side may be electrically connected through a fourth connection portion.

In the first electrode 40, the third sub-electrodes 42 and the fourth sub-electrodes 43 may extend along the first direction X or the second direction Y. The third sub-electrodes 42 and the fourth sub-electrodes 43 may be alternately arranged along the second direction Y or the first direction X. The ends of the plurality of third sub-electrodes 42 on the first side may be electrically connected through the first connection portion 441 to form a “comb-shaped” electrode. The ends of the plurality of fourth sub-electrodes 43 on the second side may be electrically connected through the second connection portion 442 to form another “comb-shaped” electrode. The first side may be opposite to the second side.

Similarly, in the second electrode 50, the fifth sub-electrodes 52 and the sixth sub-electrodes 53 may also extend along the first direction X or the second direction Y. The fifth sub-electrodes 52 and the sixth sub-electrodes 53 may be alternately arranged along the second direction Y or the first direction X. The ends of the plurality of fifth sub-electrodes 52 on the first side may be electrically connected through the first connection portion 441 to form a “comb-shaped” electrode. The ends of the plurality of sixth sub-electrodes 53 on the second side may be electrically connected through the second connection portion 442 to form another “comb-shaped” electrode. The first side may be opposite to the second side. Specifically, the third sub-electrodes 42, the fourth sub-electrodes 43, the fifth sub-electrodes 52, and the sixth sub-electrodes 53 may extend in a same direction. In this way, an overlapping area between the third sub-electrodes 42 and the sixth sub-electrodes 53 and an overlapping area between the fourth sub-electrodes 43 and the fifth sub-electrodes 52 in a direction perpendicular to the display panel 100 may both be relatively great. A preset electric field may be better formed, and the state of the light modulation structure 30 may be better controlled.

Specifically, when the first preset electric field is formed between the third sub-electrode 42 and the sixth sub-electrode 53, the third light modulation layer may be in the transparent state. When the first preset electric field is formed between the fourth sub-electrode 43 and the fifth sub-electrode 52, the second light modulation layer may be in the transparent state. When the second preset electric field is formed between the fourth sub-electrode 43 and the sixth sub-electrode 53, the first light modulation layer may be in the transparent state.

When the second preset electric field is formed between the third sub-electrode 42 and the sixth sub-electrode 53, the third light modulation layer may be in the opaque state. When the second preset electric field is formed between the fourth sub-electrode 43 and the fifth sub-electrode 52, the second light modulation layer may be in the opaque state. When the first preset electric field is formed between the fourth sub-electrode 43 and the sixth sub-electrode 53, the first light modulation layer may be in the opaque state.

As illustrated in FIG. 28, FIG. 28 is a schematic diagram of light emission of the display panel in FIG. 26 in the second wide-view display mode. In some embodiments, when the third sub-electrode 42 and the sixth sub-electrode 53 form the first preset electric field, the fourth sub-electrode 43 and the fifth sub-electrode 52 form the first preset electric field, and the fourth sub-electrode 43 and the sixth sub-electrode 53 form the second preset electric field, each of the first light modulation layer, the second light modulation layer, and the third light modulation layer may be in the transparent state, and the display panel 100 may be in a second wide-view display mode.

In this display mode, each of the first light modulation layer, the second light modulation layer, and the third light modulation layer of the light modulation structure 30 may be in the transparent state. Similar to the previous embodiments, in this mode, when the high-resolution display is required, both types of the first sub-pixels 61 and the second sub-pixels 62 are turned on to participate in the image display. When the high-resolution display is not required, only one type of the first sub-pixels 61 or the second sub-pixels 62 may be turned on to participate in the image display to reduce power consumption. Alternatively, the display surface may be partitioned into the high-resolution region 105 and the low-resolution region 106. In the high-resolution region, both types of the first sub-pixels 61 and the second sub-pixels 62 may be turned on to participate in the image display. In the low-resolution region 106, only one type of the first sub-pixels 61 or the second sub-pixels 62 may be turned on to participate in the image display. In this way, the high-quality display may be maintained, and the power consumption may be appropriately reduced. Specifically, switching among these three display modes may be performed according to user requirements.

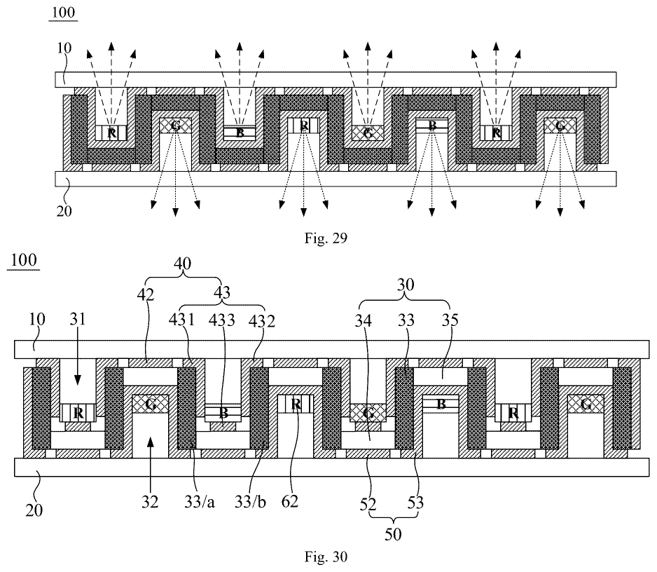

As illustrated in FIG. 29, FIG. 29 is a schematic diagram of light emission of the display panel in FIG. 26 in the second narrow-view display mode. In some embodiments, when the third sub-electrode 42 and the sixth sub-electrode 53 form the second preset electric field, the fourth sub-electrode 43 and the fifth sub-electrode 52 form the second preset electric field, and the fourth sub-electrode 43 and the sixth sub-electrode 53 form the first preset electric field, each of the first light modulation layer, the second light modulation layer, and the third light modulation layer may be in the opaque state, and the display panel 100 may be in a second narrow-view display mode.

In this display mode, each of the first light modulation layer, the second light modulation layer, and the third light modulation layer of the light modulation structure 30 may be in the opaque state. Similar to the previous embodiments, this display mode may meet the anti-peeping requirement. Meanwhile, when double-sided display may be required, both types of the first sub-pixels 61 and the second sub-pixels 62 are turned on to display images respectively, and the images displayed by the first sub-pixels 61 and the second sub-pixels 62 may be the same or different, which may be set according to actual requirements. When only the first substrate 10 side may be required to display, only the first sub-pixels 61 may be turned on, and the second sub-pixels 62 may be turned off. When only the second substrate 20 side may be required to display, only the second sub-pixels 62 may be turned on, and the first sub-pixels 61 may be turned off.

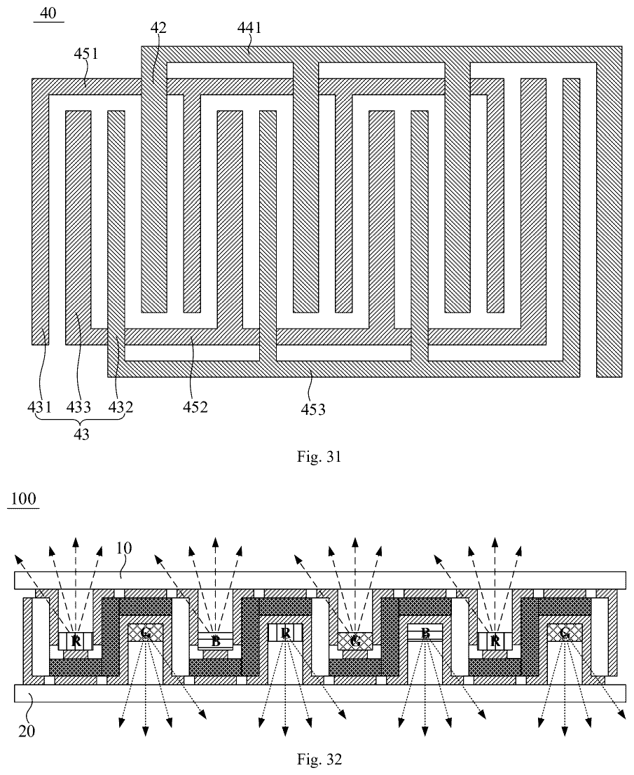

As illustrated in FIG. 30 and FIG. 31, FIG. 30 is a schematic structural diagram of the display panel in a seventh embodiment of the present disclosure, and FIG. 31 is a schematic planar structural diagram of the first electrode of FIG. 30. In some embodiments, the fourth sub-electrode 43 may be further divided. The fourth sub-electrode 43 includes a first side electrode 431, a bottom wall electrode 433, and a second side electrode 432. The first side electrode 431 may be arranged on a side wall surface of the first groove 31. The second side electrode 432 may be arranged on another side wall surface of the first groove 31. The bottom wall electrode 433 may be arranged on a bottom wall surface of the first groove 31.

In some embodiments, ends of the third sub-electrodes 42 on a same side may be electrically connected through the first connection portion 441. Ends of the first side electrodes 431 on a same side may be electrically connected through a first sub-connection portion 451. Ends of the second side electrodes 432 on a same side may be electrically connected through a second sub-connection portion 453. Ends of the bottom wall electrodes 433 on a same side may be electrically connected through a third sub-connection portion 452. Ends of the fifth sub-electrodes 52 on a same side may be electrically connected through the third connection portion. Ends of the sixth sub-electrodes 53 on a same side may be electrically connected through the fourth connection portion.

The extending directions of the first side electrode 431, the bottom wall electrode 433, and the second side electrode 432 may be the same as that of the third sub-electrode 42. Ends of a plurality of first side electrodes 431 on the first side may be electrically connected through the first sub-connection portion 451 to form a “comb-shaped” electrode. Ends of a plurality of second side electrodes 432 on the second side may be electrically connected through the second sub-connection portion 453 to form another “comb-shaped” electrode. Ends of the bottom wall electrodes 433 on the second side may be electrically connected through the third sub-connection portion 452 to form another “comb-shaped” electrode. The first side may be opposite to the second side. Specifically, specific structures of the fourth sub-electrode 43 and the fifth sub-electrode 52 may be the same as those in the previous embodiments.

Specifically, when the first side electrode 431 and the sixth sub-electrode 53 form the second preset electric field, the first light modulation layer 33 provided with the first side electrode 431 may be in the transparent state. That is, the first light modulation layer 33 on a side of the first groove 31 may be defined as a first light modulation layer 33/a. When the second side electrode 432 and the sixth sub-electrode 53 form the second preset electric field, the first light modulation layer 33 provided with the second side electrode 432 may be in the transparent state. That is, the first light modulation layer 33 on another side of the first groove 31 may be defined as a first light modulation layer 33/b. When the third sub-electrode 42 and the sixth sub-electrode 53 form the first preset electric field, the third light modulation layer 35 may be in the transparent state. When the bottom wall electrode 433 and the fifth sub-electrode 52 form the first preset electric field, the second light modulation layer 34 may be in the transparent state.

When the first side electrode 431 and the sixth sub-electrode 53 form a first preset electric field, the first light modulation layer 33/a may be in the opaque state. When the second side electrode 432 and the sixth sub-electrode 53 form the first preset electric field, the first light modulation layer 33/b may be in the opaque state. When the third sub-electrode 42 and the sixth sub-electrode 53 form the second preset electric field, the third light modulation layer 35 may be in the opaque state. When the bottom wall electrode 433 and the fifth sub-electrode 52 form the second preset electric field, the second light modulation layer 34 may be in the opaque state.

In the present embodiment, by dividing the fourth sub-electrode 43 into the first side electrode 431, the bottom wall electrode 433, the second side electrode 432, wherein the first side electrode 431 matches with the first light modulation layer 33/a on a side of the first groove 31, the bottom wall electrode 433 matches with the bottom wall of the first groove 31, and the second side electrode 432 matches with the first light modulation layer 33/b on another side of the first groove 31, thus the first light modulation layer 33/a on one side of the first sub-pixels 61 and the first light modulation layer 33/b on the another side of the first sub-pixels 61 may be further enabled to be independently controlled. In this way, in addition to the display modes in the previous embodiments, the display panel 100 may also realize more display modes as follows, so that the display panel 100 may adapt to more usage scenarios.

As illustrated in FIG. 32, FIG. 32 is a schematic diagram of light emission of the display panel in FIG. 30 in a double-sided first lateral view display mode. In some embodiments, when the first side electrode 431 and the sixth sub-electrode 53 form the second preset electric field, the bottom wall electrode 433 and the fifth sub-electrode 52 form the second preset electric field, the third sub-electrode 42 and the sixth sub-electrode 53 form the second preset electric field, and the second side electrode 432 and the sixth sub-electrode 53 form the first preset electric field, the first light modulation layer provided with the second side electrode 432 may be in the opaque state, the second light modulation layer may be in the opaque state, the third light modulation layer may be in the opaque state may be in the opaque state, and the first light modulation layer provided with the first side electrode 431 may be in the transparent state. The display panel 100 may be in the double-sided first lateral view display mode.

Specifically, taking the first side as the left side as an example, in this display mode, only the first light modulation layer 33/a is in the transparent state; the first light modulation layer 33/b, the second light modulation layer, and the third light modulation layer may be all in the opaque state. In this state, the first light modulation layer 33/a on the left side of the first sub-pixels 61 may not block the emitted light of the first sub-pixels 61, so that the first sub-pixels 61 may display towards a front view and a left-side view, while no display content may be seen from a right-side view. Similarly, taking the second sub-pixels 62 as the main body, the first light modulation layer 33/a on the left side of the second sub-pixels 62 may not block the emitted light of the second sub-pixels 62, so that the second sub-pixels 62 may display towards the front view and the left-side view, while no display content may be seen from the right-side view.

It should be appreciated that, in some embodiments, only the first sub-pixels 61 may be turned on, and the second sub-pixels 62 may be turned off, so that the display panel 100 may only display on the first substrate 10 side, and may display in the front view and the left-side view. In some embodiments, alternatively, only the second sub-pixels 62 may be turned on, and the first sub-pixels 61 may be turned off as required, so that the display panel 100 may only display on the second substrate 20 side and display in the front view and the left-side view. By turning off the first sub-pixels 61 or the second sub-pixels 62, the single-sided front view and left-side view display may be realized.

In some embodiments, taking the case where the first preset electric field may be formed when the voltage difference between the two electrodes is 5V and the second preset electric field may be formed when the voltage difference between the two electrodes is 0V as an example, the first side electrode 431 may be 0V, the sixth sub-electrode 53 may be 0V, the second side electrode 432 may be 5V or (−5)V, the bottom wall electrode 433 may be 0V, the third sub-electrode 42 may be 0V, and the fifth sub-electrode 52 may be 0V. In this way, the above-mentioned double-sided or single-sided first lateral view display mode may be realized.

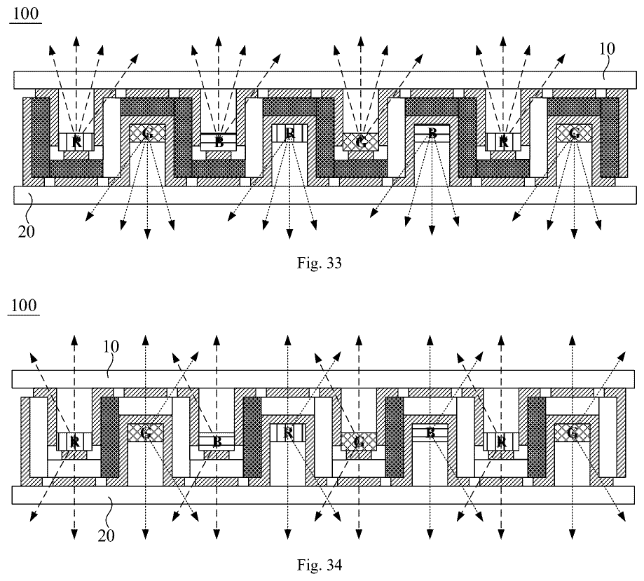

As illustrated in FIG. 33, FIG. 33 is a schematic diagram of light emission of the display panel in FIG. 30 in the double-sided second lateral view display mode. In some embodiments, when the first side electrode 431 and the sixth sub-electrode 53 form the first preset electric field, the bottom wall electrode 433 and the fifth sub-electrode 52 form the second preset electric field, the third sub-electrode 42 and the sixth sub-electrode 53 form the second preset electric field, and the second side electrode 432 and the sixth sub-electrode 53 form the second preset electric field, the first light modulation layer provided with the first side electrode 431 may be in the opaque state, the second light modulation layer may be in the opaque state, the third light modulation layer may be in the opaque state, and the first light modulation layer provided with the second side electrode 432 may be in the transparent state. The display panel 100 may be in the double-sided second lateral view display mode.

Specifically, taking the second side as the right side as an example, in this display mode, only the first light modulation layer 33/b is in the transparent state; the first light modulation layer 33/a, the second light modulation layer, and the third light modulation layer may be all in the opaque state. In this state, the first light modulation layer 33/b on the right side of the first sub-pixels 61 may not block the emitted light of the first sub-pixels 61, so that the first sub-pixels 61 may display towards the front view and the right-side view, while no display content may be seen from the left-side view. Similarly, taking the second sub-pixels 62 as the main body, the first light modulation layer 33/b on the right side of the second sub-pixels 62 may not block the emitted light of the second sub-pixels 62, so that the second sub-pixels 62 may display towards the front view and the right-side view, while no display content may be seen from the left-side view.

It should be appreciated that, in some embodiments, only the first sub-pixels 61 may be turned on, and the second sub-pixels 62 may be turned off, so that the display panel 100 may only display on the first substrate 10 side, and may display in the front view and the right-side view. In some embodiments, alternatively, only the second sub-pixels 62 may be turned on, and the first sub-pixels 61 may be turned off as required, so that the display panel 100 may only display on the second substrate 20 side and display in the front view and the right-side view. By turning off the first sub-pixels 61 or the second sub-pixels 62, the single-sided front view and right-side view display may be realized.

In some embodiments, taking the case where the first preset electric field may be formed when the voltage difference between the two electrodes is 5V and the second preset electric field may be formed when the voltage difference between the two electrodes is 0V as an example, the first side electrode 431 may be 5V or (−5)V, the sixth sub-electrode 53 may be 0V, the second side electrode 432 may be 0V, the bottom wall electrode 433 may be 0V, the third sub-electrode 42 may be 0V, and the fifth sub-electrode 52 may be 0V. In this way, the above-mentioned double-sided or single-sided first lateral view display mode may be realized.

As illustrated in FIG. 34, FIG. 34 is a schematic diagram of light emission of the display panel in FIG. 30 in a double-sided dual-lateral view display mode. In some embodiments, when the third sub-electrode 42 and the sixth sub-electrode 53 form the first preset electric field, the first side electrode 431 and the sixth sub-electrode 53 form the second preset electric field, the bottom wall electrode 433 and the fifth sub-electrode 52 form the first preset electric field, and the second side electrode 432 and the sixth sub-electrode 53 form the first preset electric field, the second light modulation layer may be in the transparent state, the first light modulation layer provided with the first side electrode 431 may be in the transparent state, the third light modulation layer may be in the transparent state, and the first light modulation layer provided with the second side electrode 432 may be in the opaque state. The display panel 100 may be in the double-sided dual-lateral view display mode.

Specifically, taking the first side as the left side and the second side as the right side as an example, in the present display mode, one of the first light modulation layer 33/a and the first light modulation layer 33/b may be in the transparent state, and another may be in the opaque state; the second light modulation layer and the third light modulation layer may be both in the transparent state. In the present embodiment, a case in which the first light modulation layer 33/a is in the transparent state, and the first light modulation layer 33/b is in the opaque state may be taken as an example.

In this state, the first sub-pixels 61 and the second sub-pixels 62 may display towards both the first substrate 10 side and the second substrate 20 side. On the first substrate 10 side, since the first light modulation layer 33/a and the third light modulation layer are transparent, the first sub-pixels 61 may display towards the front view and the left-side view, and the second sub-pixels 62 may display towards the front view and the right-side view. Similarly, on the second substrate 20 side, since the first light modulation layer 33/a and the second light modulation layer are transparent, the first sub-pixels 61 may also display towards the front view and the left-side view, and the second sub-pixels 62 may display towards the front view and the right-side view.

In this display mode, the content displayed by the first sub-pixels 61 may be viewed from the left-side view, and the content displayed by the second sub-pixels 62 may be viewed from the right-side view. The display content of the left-side view and the right-side view may not interfere with each other, so that one screen may be used for two purposes. In this display mode, the user on the left-side view may watch the first display content, and the user on the right-side view may watch the second display content. The first display screen and the second display screen may be the same or different. For example, this mode may be used in a vehicle driving scenario. The view of the display panel 100 towards the driver's side may be configured to display navigation information and vehicle-related information. The view of the display panel 100 towards the co-driver's side may display other contents, so that the display panel 100 may not affect a driver on the driver's side and may be displayed according to requirements of the co-driver, thus one screen may be used for two purposes.

In some embodiments, taking the case where the first preset electric field is formed when the voltage difference between the two electrodes is 5V and the second preset electric field is formed when the voltage difference between the two electrodes is 0V as an example, the first side electrode 431 may be 0V, the sixth sub-electrode 53 may be 0V, the second side electrode 432 may be 0V, the bottom wall electrode 433 may be 0V, the third sub-electrode 42 may be 5V, and the fifth sub-electrode 52 may be 5V or (−5)V. In this way, the above-mentioned double-sided or single-sided first lateral view display mode may be realized.

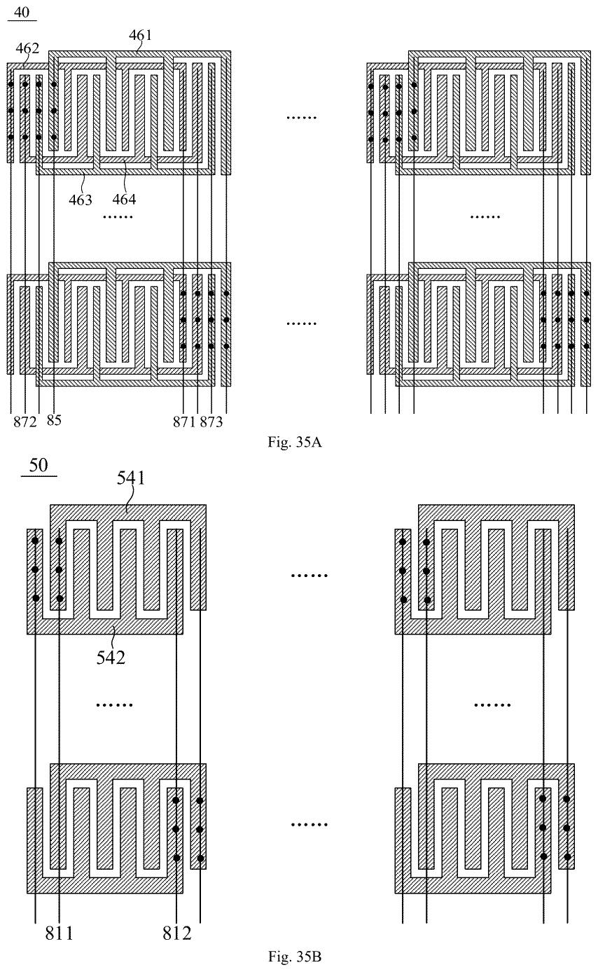

As illustrated in FIG. 30, FIG. 35a and FIG. 35b, FIG. 35a is another schematic planar structural diagram of the first electrode in FIG. 30, and FIG. 35b is a schematic planar structural diagram of the second electrode in FIG. 30. In some embodiments, the third sub-electrode 42, the first side electrode 431, the second side electrode 432, and the bottom wall electrode 433 may be respectively designed in a block manner, and independent electrode connection lines may be provided to connect each electrode block.

The ends of several adjacent third sub-electrodes 42 on a same side may be electrically connected through the first connection portion 441 to form a first functional electrode 461. A plurality of first functional electrodes 461 may be arranged in an array, and each first functional electrode 461 may be electrically connected to a matched third touch-control connection line 85.

The ends of several adjacent first side electrodes 431 on the same side may be electrically connected through the first sub-connection portion 451 to form a first lateral view electrode 462. A plurality of first lateral view electrodes 462 may be arranged in an array, and each first lateral view electrode 462 may be electrically connected to a matched first side connection line 871. Ends of several adjacent second side electrodes 432 on the same side may be electrically connected through a second sub-connection portion 453 to form a second lateral view electrode 463. A plurality of second lateral view electrodes 463 may be arranged in an array, and each second lateral view electrode 463 may be electrically connected to a matched second side connection line 873. Ends of several adjacent bottom wall electrodes 433 on the same side may be electrically connected through a third sub-connection portion 452 to form a bottom electrode 464. A plurality of bottom electrodes 464 may be arranged in an array. Each bottom electrode 464 may be electrically connected to a matched bottom electrode connection line 872.

Ends of several adjacent fifth sub-electrodes 52 on the same side may be electrically connected through a third connection portion to form a second functional electrode 541. A plurality of second functional electrodes 541 may be arranged in an array, and each second functional electrode 541 may be electrically connected to a matched fourth touch-control connection line 811. Ends of several adjacent sixth sub-electrodes 53 on the same side may be electrically connected through a fourth connection portion to form a third functional electrode 542. A plurality of third functional electrodes 542 may be arranged in an array, and each third functional electrode 542 may be electrically connected to a matched fifth touch-control connection line 812.

In some embodiments, an anode 611 of the first sub-pixels 61 may be located on the side of the light-emitting layer close to the first substrate 10. An anode 611 of the second sub-pixels 62 may be located on the side of the light-emitting layer close to the second substrate 20. It may be seen from FIG. 30 that, since the bottom wall electrode 433 may be almost completely shielded by the anode 611 of the first sub-pixels 61, the bottom electrode 464 formed by the bottom wall electrode 433 may only be used as a control electrode for the second light modulation layer, and cannot be used as a touch-control electrode, but may be reused as the cathode of the first sub-pixels 61. An area of the first side electrode 431 matching with a touch-control plane may be relatively small, and the second side electrode 432 matching with the touch-control plane may be relatively small, thus an induction amount may be small when the first side electrode 431 and the second side electrode 432 are used as touch-control electrodes. The first side electrode 431 and the second side electrode 432 may be not used as touch-control electrodes but only as control electrodes of the first light modulation layer. The first functional electrode 461 formed by the third sub-electrode 42 may be not shielded by the anode 611 of the first sub-pixels 61, and may be used as a control electrode for the third light modulation layer and as a touch-control electrode simultaneously, so as to realize a touch-control function on a display surface of the first substrate 10 side.

For the display surface at the second substrate 20 side, the fifth sub-electrode 52 may be not shielded by the anode 611 of the second sub-pixels 62, and may be used as a control electrode of the second light modulation layer and a touch-control electrode simultaneously. The part of the sixth sub-electrode 53 may be not shielded by the anode 611 of the second sub-pixels 62, and may be used as a control electrode of the first light modulation layer, a control electrode of the third light modulation layer, a cathode of the second sub-pixels 62, and a touch-control electrode simultaneously. A touch-control function at the display surface of the second substrate 20 side may be realized by reusing the fifth sub-electrode 52 and/or the sixth sub-electrode 53 as touch-control electrodes. Through the above-mentioned arrangement, the double-sided touch-control display of the display panel 100 may be realized.

It should be noted that, when preparing the display panel 100, the present embodiment may perform fusion and reuse of the cathode, the touch-control electrode, and the control electrode of the light modulation structure 30. Thus, the first electrode 40 and the second electrode 50 need to be disconnected at corresponding positions for block processing. The blocking processing may be specifically performed by a patterning process. At the same time, due to an introduction of the touch-control connection lines, insulating layers may need to be arranged between the electrode block and the connection line matching with each electrode block, and the electrode block may be connected to corresponding electrode blocks through vias. In this way, a situation that the connection lines may be not in contact with other electrode blocks may be avoided. This situation may affect a normal touch-control.

Specifically, when the display panel 100 displays images frame by frame, each frame time may include a display phase T1 and a touch-control phase T2. In the display phase T1, the first functional electrode 461 may be used as a control electrode of the third light modulation layer, the first lateral view electrode 462 may be used as a control electrode of a matched first light modulation layer, the second lateral view electrode 463 may be used as a control electrode of a matched first light modulation layer, the bottom electrode 464 may be used as a cathode of the first sub-pixels 61 and a control electrode of the second light modulation layer, and the bottom electrode 464 may output a cathode signal.

In the touch-control phase T2, the first functional electrode 461 may be used as a third touch-control electrode for transmitting a third touch-control signal; the second functional electrode 541 may be used as a fourth touch-control electrode for transmitting a fourth touch-control signal; and a first difference or a second difference may be maintained between the third touch-control signal and a voltage signal of the sixth sub-electrode 53 to maintain the transparent state or the opaque state of the second light modulation layer; the first difference or the second difference may be maintained between the fourth touch-control signal and a voltage signal of the bottom wall electrode 433 to maintain the transparent state or the opaque state of the third light modulation layer.

Through the above-mentioned arrangement, and through reuse of each electrode, the display panel 100 may realize the touch-control function while realizing the above-mentioned display modes. The reuse and function fusion of the electrodes may be realized without additionally adding touch-control electrode blocks.

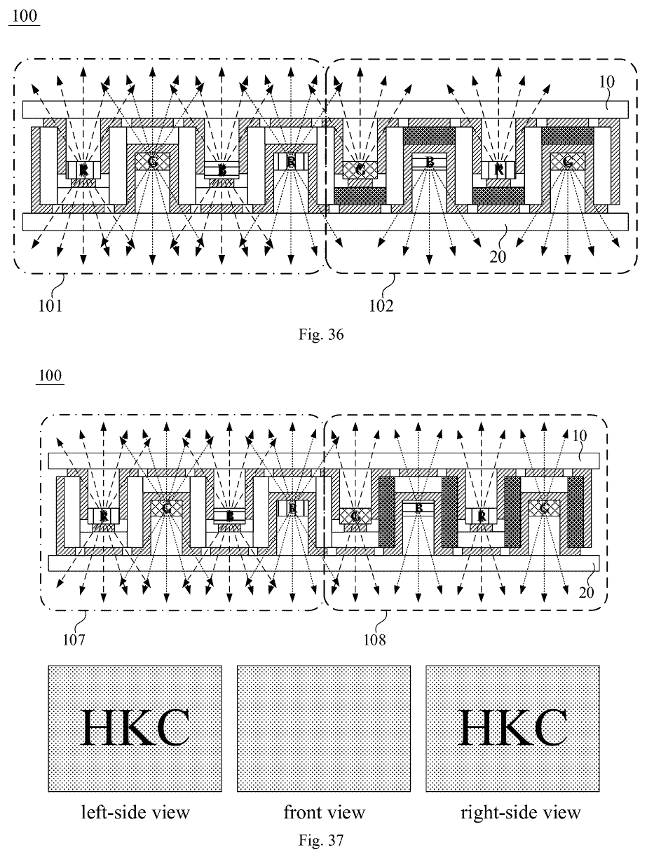

As illustrated in FIG. 36, FIG. 36 is a schematic diagram of light emission of the display panel of FIG. 30 in a mixed display mode. Further, while realizing the touch-control function, in the present embodiment, the display panel 100 may include a first display region 101 and a second display region 102. In the first display region 101, the first light modulation layer, the second light modulation layer, and the third light modulation layer may be all in the transparent state, and the first sub-pixels 61 and the second sub-pixels 62 cooperatively display a first image. In the second display region 102, the first light modulation layer may be in the transparent state, the second light modulation layer and the third light modulation layer may be in the opaque state. The first sub-pixels 61 may display a second image towards the first substrate 10. The second sub-pixels 62 may displays a third image towards the second substrate 20. The second image and the third image may have the same content but reverse display directions.

It should be easily understood that, due to the double-sided transparent display, when the content displayed by the display panel 100 includes text, the text content may be normal on one display surface, and while the text content on another surface may be mirrored, which may be not conducive to user reading. In the present embodiment, through partitioned display, the second light modulation layer and the third light modulation layer in the second display region 102 may be in the opaque state, so that the display surface at a side of the first sub-pixels 61 towards the first substrate 10 may display normal text content, and the display surface at the side of the second sub-pixels 62 towards the second substrate 20 may display normal text content. The first sub-pixels 61 and the second sub-pixels 62 do not affect the display of the opposite side, thereby solving the problem of mirrored text display. Meanwhile, in the first display region 101, the second light modulation layer and the third light modulation layer may be in the transparent state, and may perform the double-sided display. The first sub-pixels 61 and the second sub-pixels 62 may cooperatively participate in displaying the same image frame for high-resolution display, thereby ensuring the fineness of the image.

In some embodiments, in the display mode, the first light modulation layer in the first display region 101 and/or the first light modulation layer in the second display region 102 may be in the transparent state or in the opaque state. In this way, the wide-view or anti-peeping requirements, or the left and/or right view display requirements may be met.

As illustrated in FIG. 37, FIG. 37 is a schematic display diagram of the display panel in FIG. 30 in an identification display mode. In some embodiments, the display panel 100 may include a conventional display region 107 and an identification display region 108. A shape of the identification display region 108 may be the same as that of the identification pattern. The first light modulation layer may be in the transparent state in the conventional display region 107. The first light modulation layer may be in the opaque state in the identification display region 108.

The identification display region 108 may be a region where the first light modulation layer for displaying the identification is located. That is, the shape of the identification display region 108 may be the same as a pattern shape of the identification to be displayed. Since the first side electrode 431, the second side electrode 432, and the bottom wall electrode 433 for controlling the first light modulation layer are designed in blocks, the state of the first light modulation layer may be controlled in blocks. Therefore, through block control of the first light modulation layer, the first light modulation layer at specific positions may present some identification patterns.

In the present embodiment, in the identification display region 108, by controlling the voltage difference of the control electrodes of the first light modulation layer, the first light modulation layer in the identification display region 108 may be in the opaque state. In the conventional display region 107, by controlling the voltage difference of the control electrodes of the first light modulation layer, the first light modulation layer in the conventional display region 107 may be in the transparent state. That is, by making the states of the first light modulation layer in the conventional display region 107 and the identification display region 108 form a contrast, a dark pattern identification function for the left view and the right view may be realized without affecting normal image display.

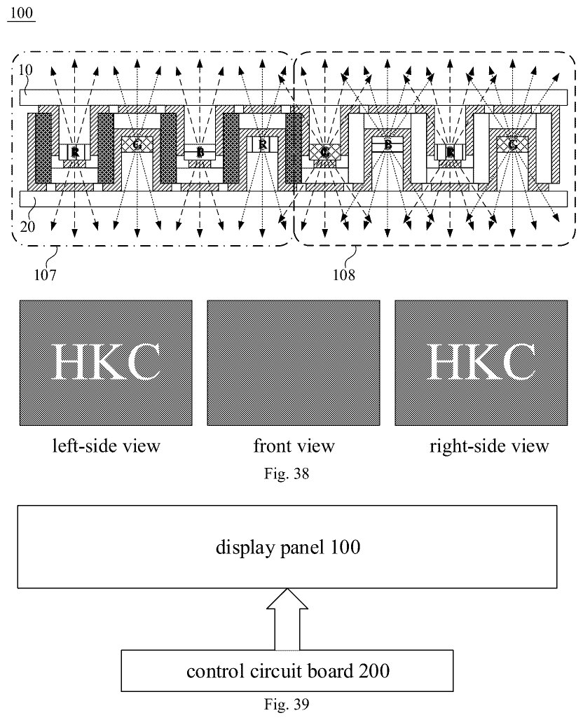

As illustrated in FIG. 38, FIG. 38 is a schematic display diagram of the display panel of FIG. 30 in another identification display mode. In some embodiments, the display panel 100 may include the conventional display region 107 and the identification display region 108. The shape of the identification display region 108 may be the same as that of the identification pattern. The first light modulation layer may be in the opaque state in the conventional display region 107. The first light modulation layer may be in the transparent state in the identification display region 108.

Different from the embodiment in FIG. 37, in the present embodiment, the first light modulation layer may be controlled to be in the transparent state in the identification display region 108, and the first light modulation layer may be controlled to be in the opaque state in the conventional display region 107. Similarly, by making the states of the first light modulation layer in the conventional display region 107 and the identification display region 108 form a contrast, a bright pattern identification function for the left view and the right view may be realized without affecting the normal image display.

As illustrated in FIG. 39, FIG. 39 is a schematic structural view of an embodiment of a display apparatus according to the present disclosure. In the present embodiment, the display apparatus may be provided. The display apparatus may include the display panel 100 and a control circuit board 200.

The display panel 100 may be the display panel 100 provided in the above-mentioned embodiments, which may realize all the functions and technical effects of the display panel 100 in the above-mentioned embodiments. For details, reference may be made to the detailed description above, which will not be repeated here.

The control circuit board 200 may be electrically connected to the display panel 100. The control circuit board 200 may be configured to control the display panel 100 to display images in a matched display mode, so as to realize the functions and technical effects involved in the above-mentioned embodiments.

The above-mentioned may be only implementations of the present disclosure, and do not limit the patent scope of the present disclosure. Any equivalent changes to the structure or processes made by the description and drawings of the present disclosure or directly or indirectly used in other related technical field may be included in the protection scope of the present disclosure.

1. A display panel, comprising:
a first substrate;
a second substrate, arranged opposite to the first substrate;
a light modulation structure, arranged between the first substrate and the second substrate; wherein a plurality of first grooves are defined on a side of the light modulation structure close to the first substrate, and a plurality of the second grooves are defined on a side of the light modulation structure close to the second substrate; the plurality of first grooves and the plurality of the second grooves are alternately defined in sequence along each of a first direction and a second direction, the first direction and the second direction are parallel to the light modulation structure, and the first direction and the second direction intersect with each other;
a first electrode, arranged on the side of the light modulation structure close to the first substrate;
a second electrode, arranged on the side of the light modulation structure close to the second substrate; wherein the second electrode is configured to form a preset electric field with the first electrode, the preset electric field is configured to control a light transmittance of the light modulation structure;
a plurality of first sub-pixels, wherein each of the plurality of first sub-pixels is arranged within one of the plurality of first grooves; and
a plurality of second sub-pixel, wherein each of the plurality of second sub-pixels is arranged within one of the plurality of second groove.

2. The display panel as claimed in claim 1, wherein
in a case where the first electrode and the second electrode form a first preset electric field, the light modulation structure is opaque, the display panel is in a narrow-view display mode; in a case where the plurality of first sub-pixels and the plurality of second sub-pixels are turned on, the display panel is in a narrow-view double-sided display mode; in a case where the plurality of first sub-pixels or the plurality of second sub-pixels are turned on, the display panel is in a narrow-view single-sided display mode;
in a case where the first electrode and the second electrode form a second preset electric field, the light modulation structure is transparent, the display panel is in a wide-view display mode; in a case where the plurality of first sub-pixels and the plurality of second sub-pixels are turned on, the display panel is in a wide-view high-resolution display mode; in a case where the plurality of first sub-pixels or the plurality of second sub-pixels are turned on, the display panel is in a wide-view low-resolution display mode.

3. The display panel as claimed in claim 1, wherein
the first electrode comprises a plurality of first sub-electrodes, the plurality of first sub-electrodes are distributed in an array and insulated from each other; a first insulating layer is further provided between the first electrode and the first substrate, a plurality of first vias are further provided in the first insulating layer; a first touch-control connection line is provided between the first insulating layer and the first substrate, the first touch-control connection line is electrically connected to matched one of the plurality of first sub-electrodes through matched one of the plurality of first vias, and the first touch-control connection line is configured to transmit a first touch-control signal;
the second electrode comprises a plurality of second sub-electrodes, the plurality of second sub-electrodes are distributed in an array and insulated from each other; a second insulating layer is further provided between the second electrode and the second substrate, a plurality of second vias are further provided in the second insulating layer; a second touch-control connection line is provided between the second insulating layer and the second substrate, the second touch-control connection line is electrically connected to matched one of the plurality of second sub-electrodes through matched one of the plurality of second vias, and the second touch-control connection line is configured to transmit a second touch-control signal;
a first gap between two adjacent ones of the plurality of first sub-electrodes is defined at a sidewall of one of the plurality of first grooves, a second gap between two adjacent ones of the plurality of second sub-electrodes is defined at a sidewall of one of the plurality of second grooves, the first gap and the second gap defined at two opposite sides of a same side wall are misaligned.

4. The display panel as claimed in claim 3, wherein
each image frame comprises a display phase and a touch-control phase;
in the display phase, at least one of the plurality of first sub-electrodes serves as a cathode of matched one of plurality of first sub-pixels, and is configured to transmit a first cathode signal; at least one of the plurality of second sub-electrodes serves as a cathode of matched one of plurality of second sub-pixels, and is configured to transmit a second cathode signal; and, a first difference or a second difference is maintained between the first cathode signal and the second cathode signal, one of the first difference and the second difference is configured to maintain a transparent state of the light modulation structure, another of the first difference and the second difference is configured to maintain an opaque state of the light modulation structure;
in the touch-control phase, at least one of the plurality of first sub-electrodes serves as a first touch-control electrode for transmitting a first touch-control signal; at least one of the plurality of second sub-electrodes serves as a second touch-control electrode for transmitting a second touch-control signal; and, a first difference or a second difference is maintained between the first touch-control signal and the second touch-control signal, one of the first difference and the second difference is configured to maintain the transparent state of the light modulation structure, another of the first difference and the second difference is configured to maintain the opaque state of the light modulation structure.

5. The display panel as claimed in claim 1, wherein
the first insulating layer, one or more first scan touch-control electrodes, one or more first data touch-control electrodes, the second insulating layer, a first scan line, a third insulating layer, and a first data line are sequentially stacked on a side of the first electrode close to the first substrate; the one or more first scan touch-control electrodes and the one or more first data touch-control electrodes are distributed in an array, and the one or more first scan touch-control electrodes are insulated from the one or more first data touch-control electrodes, the one or more first scan touch-control electrodes in a same row are connected to a same first scan line, the one or more first data touch-control electrodes in a same column are connected to a same first data line;
a fourth insulating layer, one or more second scan touch-control electrodes, one or more second data touch-control electrodes, a fifth insulating layer, a second scan line, a sixth insulating layer, and a second data line are sequentially stacked on a side of the second electrode close to the second substrate; wherein the one or more second scan touch-control electrodes and the one or more second data touch-control electrodes are distributed in an array, and the one or more second scan touch-control electrodes are insulated from the one or more second data touch-control electrodes, the one or more second scan touch-control electrodes in a same row are connected to a same second scan line, the one or more second data touch-control electrodes in a same column are connected to a same second data line.

6. The display panel as claimed in claim 1, wherein
the light modulation structure comprises a first light modulation layer, a second light modulation layer, and a third light modulation layer; a sidewall at a side, where one of the plurality of first grooves and one of the plurality of second grooves are adjacent to each other, is the first light modulation layer, a bottom wall of the one of the plurality of first grooves close to the second substrate is the second light modulation layer, a bottom wall of the one of the plurality of second grooves close to the first substrate is the third light modulation layer; the light modulation structure comprises an opaque state and a transparent state; under an action of a same preset electric field, the transparent state of the second light modulation layer is reverse to that of the first light modulation layer, and the transparent state of the third light modulation layer is reverse to that of the first light modulation layer.

7. The display panel as claimed in claim 6, wherein
in a case where the first electrode and the second electrode form a second preset electric field, the first light modulation layer is in the transparent state, the second light modulation layer and the third light modulation layer are in the opaque state, the display panel is in a first wide-view display mode;
in a case where the first electrode and the second electrode form a first preset electric field, the first light modulation layer is in the opaque state, the second light modulation layer and the third light modulation layer are in the transparent state, the display panel is in a first narrow-view display mode.

8. The display panel as claimed in claim 6, wherein
the first electrode comprises one or more third sub-electrodes and one or more fourth sub-electrodes, the one or more third sub-electrodes are insulated from the one or more fourth sub-electrodes, the one or more third sub-electrodes are arranged on a side surface of the third light modulation layer close to the first substrate; the one or more fourth sub-electrodes are arranged on a groove wall surface of one of the plurality of first grooves and on a side surface of the first light modulation layer close to the first substrate, wherein the first light modulation layer is adjacent to the one of the plurality of first grooves;
the second electrode comprises one or more fifth sub-electrodes and one or more sixth sub-electrodes, the one or more fifth sub-electrodes are insulated from the one or more sixth sub-electrodes, the one or more fifth sub-electrodes are arranged on a side surface of the second light modulation layer close to the second substrate; the one or more sixth sub-electrodes are arranged on a groove wall surface of one of the plurality of second grooves and on a side surface of the first light modulation layer close to the second substrate, wherein the first light modulation layer is adjacent to the one of the plurality of second grooves.

9. The display panel as claimed in claim 8, wherein
ends of the one or more third sub-electrodes on a same side are electrically connected through a first connection portion, ends of the one or more fourth sub-electrodes on a same side are electrically connected through a second connection portion, ends of the one or more fifth sub-electrodes on a same side are electrically connected through a third connection portion, and, ends of the one or more sixth sub-electrodes on a same side are electrically connected through a fourth connection portion; wherein
in a case where the third sub-electrode and the sixth sub-electrode form a first preset electric field, the fourth sub-electrode and the fifth sub-electrode form the first preset electric field, and the fourth sub-electrode and the sixth sub-electrode form a second preset electric field, each of the first light modulation layer, the second light modulation layer, and the third light modulation layer is in the transparent state, the display panel is in a second wide-view display mode;
in a case where the third sub-electrode and the sixth sub-electrode form a second preset electric field, the fourth sub-electrode and the fifth sub-electrode form the second preset electric field, and the fourth sub-electrode and the sixth sub-electrode form a first preset electric field, each of the first light modulation layer, the second light modulation layer, and the third light modulation layer is in the opaque state, the display panel is in a second narrow-view display mode.

10. The display panel as claimed in claim 8, wherein
each of the one or more fourth sub-electrodes comprises a first side electrode, a bottom wall electrode, and a second side electrode, the first side electrode is arranged on a side wall surface of one of the plurality of first grooves, the second side electrode is arranged on another side wall surface of the one of the plurality of first grooves, the bottom wall electrode is arranged on a bottom wall surface of the one of the plurality of first grooves.

11. The display panel as claimed in claim 10, wherein
ends of the one or more third sub-electrodes on a same side are electrically connected through a first connection portion; ends of one or more first side electrodes on a same side are electrically connected through a first sub-connection portion, ends of one or more second side electrodes on a same side are electrically connected through a second sub-connection portion, ends of one or more bottom wall electrodes on a same side are electrically connected through a third sub-connection portion; ends of the one or more fifth sub-electrodes on a same side are electrically connected through a third connection portion, and, ends of the one or more sixth sub-electrodes on a same side are electrically connected through a fourth connection portion;
in a case where the first side electrode and the sixth sub-electrode form a second preset electric field, the bottom wall electrode and the fifth sub-electrode form the second preset electric field, and the third sub-electrode and the sixth sub-electrode form the second preset electric field, and the second side electrode and the sixth sub-electrode form a first preset electric field, each of the first light modulation layer provided with the second side electrode, the second light modulation layer, and the third light modulation layer is in the opaque state, the first light modulation layer provided with the first side electrode is in the transparent state, the display panel is in a double-sided first lateral view display mode;
in a case where the first side electrode and the sixth sub-electrode form a first preset electric field, the bottom wall electrode and the fifth sub-electrode form a second preset electric field, the third sub-electrode and the sixth sub-electrode form the second preset electric field, and the second side electrode and the sixth sub-electrode form the second preset electric field, each of the first light modulation layer provided with the first side electrode, the second light modulation layer, and the third light modulation layer is in the opaque state, the first light modulation layer provided with the second side electrode is in the transparent state, the display panel is in a double-sided second lateral view display mode;
in a case where the third sub-electrode and the sixth sub-electrode form the first preset electric field, the first side electrode and the sixth sub-electrode form the second preset electric field, the bottom wall electrode and the fifth sub-electrode form the first preset electric field, the second side electrode and the sixth sub-electrode form the first preset electric field, each of the second light modulation layer, the first light modulation layer provided with the first side electrode, and the third light modulation layer is in the transparent state, the first light modulation layer provided with the second side electrode is in the opaque state, and the display panel is in a double-sided dual-lateral view display mode.

12. The display panel as claimed in claim 10, wherein
the ends of several adjacent ones of the one or more third sub-electrodes on a same side are electrically connected through a first connection portion to form one or more first functional electrodes, the one or more first functional electrodes are arranged in an array, and each of the one or more first functional electrodes is electrically connected to a matched third touch-control connection line;
the ends of several adjacent ones of the one or more first sub-electrodes on a same side are electrically connected through a first sub-connection portion to form one or more first lateral view electrodes, the one or more first lateral view electrodes are arranged in an array, and each of the one or more first lateral view electrodes is electrically connected to a matched first side connection line; the ends of several adjacent ones of the one or more second sub-electrodes on a same side are electrically connected through a second sub-connection portion to form one or more second lateral view electrodes, the one or more second lateral view electrodes are arranged in an array, and each of the one or more second lateral view electrodes is electrically connected to a matched second side connection line; the ends of several adjacent ones of the one or more bottom wall electrodes on a same side are electrically connected through a third sub-connection portion to form one or more bottom electrodes, the one or more bottom electrodes are arranged in an array, and each of the one or more bottom electrodes is electrically connected to a matched bottom electrode connection line;
the ends of several adjacent ones of the one or more fifth sub-electrodes on a same side are electrically connected through a third connection portion to form one or more second functional electrodes, the one or more second functional electrodes are arranged in an array, and each of the one or more second functional electrodes is electrically connected to a matched fourth touch-control connection line; the ends of several adjacent ones of the one or more sixth sub-electrodes on a same side are electrically connected through a fourth connection portion to form one or more third functional electrodes, the one or more third functional electrodes are arranged in an array, and each of the one or more third functional electrodes is electrically connected to a matched fifth touch-control connection line;
each image frame comprises a display phase and a touch-control phase;
wherein in the touch-control phase, at least one of the one or more first functional electrodes serves as a third touch-control electrode, and configured to transmit a third touch-control signal; at least one of the one or more second functional electrodes serves as a fourth touch-control electrode, and configured to transmit a fourth touch-control signal; and, a first difference or a second difference is maintained between the third touch-control signal and a voltage signal of the sixth sub-electrode, one of the first difference and the second difference is configured to maintain the transparent state of the second light modulation layer, another of the first difference and the second difference is configured to maintain the opaque state of the second light modulation layer; and, a first difference or a second difference is maintained between the fourth touch-control signal and a voltage signal of the bottom wall electrode, one of the first difference and the second difference is configured to maintain the transparent state of the third light modulation layer, another of the first difference and the second difference is configured to maintain the opaque state of the third light modulation layer.

13. The display panel as claimed in claim 12, wherein
the display panel comprises a first display region and a second display region;
in the first display region, each of the first light modulation layer, the second light modulation layer, and the third light modulation layer is in the transparent state, the plurality of first sub-pixels and the plurality of second sub-pixels cooperatively display a first image;
in the second display region, the first light modulation layer is in the transparent state, each of the second light modulation layer and the third light modulation layer is in the opaque state, the plurality of first sub-pixels are configured to display a second image towards the first substrate, the plurality of second sub-pixels are configured to display a third image towards the second substrate, the second image and the third image comprise a same content, a display direction of the second picture is reverse to that of the third picture.

14. The display panel as claimed in claim 12, wherein the display panel comprises a conventional display region and an identification display region, a shape of the identification display region is the same as that of an identification pattern;
in the conventional display region, the first light modulation layer is in the transparent state; in the identification display region, the first light modulation layer is in the opaque state; or
in the conventional display region, the first light modulation layer is in the opaque state; in the identification display region, the first light modulation layer is in the transparent state.

15. A display apparatus, comprising:
a display panel; and
a control circuit board, electrically connected to the display panel, and configured to control the display panel to display an image in a matched display mode,
wherein the display panel comprises:
a first substrate;
a second substrate, arranged opposite to the first substrate;
a light modulation structure, arranged between the first substrate and the second substrate;
wherein a plurality of first grooves are defined on a side of the light modulation structure close to the first substrate, and a plurality of the second grooves are defined on a side of the light modulation structure close to the second substrate; the plurality of first grooves and the plurality of the second grooves are alternately defined in sequence along each of a first direction and a second direction, the first direction and the second direction are parallel to the light modulation structure, and the first direction and the second direction intersect with each other;
a first electrode, arranged on the side of the light modulation structure close to the first substrate;
a second electrode, arranged on the side of the light modulation structure close to the second substrate; wherein the second electrode is configured to form a preset electric field with the first electrode, the preset electric field is configured to control a light transmittance of the light modulation structure;
a plurality of first sub-pixels, wherein each of the plurality of first sub-pixels is arranged within one of the plurality of first grooves; and
a plurality of second sub-pixel, wherein each of the plurality of second sub-pixels is arranged within one of the plurality of second groove.

16. The display apparatus as claimed in claim 15, wherein
in a case where the first electrode and the second electrode form a first preset electric field, the light modulation structure is opaque, the display panel is in a narrow-view display mode; in a case where the plurality of first sub-pixels and the plurality of second sub-pixels are turned on, the display panel is in a narrow-view double-sided display mode; in a case where the plurality of first sub-pixels or the plurality of second sub-pixels are turned on, the display panel is in a narrow-view single-sided display mode;
in a case where the first electrode and the second electrode form a second preset electric field, the light modulation structure is transparent, the display panel is in a wide-view display mode; in a case where the plurality of first sub-pixels and the plurality of second sub-pixels are turned on, the display panel is in a wide-view high-resolution display mode; in a case where the plurality of first sub-pixels or the plurality of second sub-pixels are turned on, the display panel is in a wide-view low-resolution display mode.

17. The display apparatus as claimed in claim 15, wherein
the first electrode comprises a plurality of first sub-electrodes, the plurality of first sub-electrodes are distributed in an array and insulated from each other; a first insulating layer is further provided between the first electrode and the first substrate, a plurality of first vias are further provided in the first insulating layer; a first touch-control connection line is provided between the first insulating layer and the first substrate, the first touch-control connection line is electrically connected to matched one of the plurality of first sub-electrodes through matched one of the plurality of first vias, and the first touch-control connection line is configured to transmit a first touch-control signal;
the second electrode comprises a plurality of second sub-electrodes, the plurality of second sub-electrodes are distributed in an array and insulated from each other; a second insulating layer is further provided between the second electrode and the second substrate, a plurality of second vias are further provided in the second insulating layer; a second touch-control connection line is provided between the second insulating layer and the second substrate, the second touch-control connection line is electrically connected to matched one of the plurality of second sub-electrodes through matched one of the plurality of second vias, and the second touch-control connection line is configured to transmit a second touch-control signal;
a first gap between two adjacent ones of the plurality of first sub-electrodes is defined at a sidewall of one of the plurality of first grooves, a second gap between two adjacent ones of the plurality of second sub-electrodes is defined at a sidewall of one of the plurality of second grooves, the first gap and the second gap defined at two opposite sides of a same side wall are misaligned.

18. The display apparatus as claimed in claim 17, wherein
each image frame comprises a display phase and a touch-control phase;
in the display phase, at least one of the plurality of first sub-electrodes serves as a cathode of matched one of plurality of first sub-pixels, and is configured to transmit a first cathode signal; at least one of the plurality of second sub-electrodes serves as a cathode of matched one of plurality of second sub-pixels, and is configured to transmit a second cathode signal; and, a first difference or a second difference is maintained between the first cathode signal and the second cathode signal, one of the first difference and the second difference is configured to maintain a transparent state of the light modulation structure, another of the first difference and the second difference is configured to maintain an opaque state of the light modulation structure;
in the touch-control phase, at least one of the plurality of first sub-electrodes serves as a first touch-control electrode for transmitting a first touch-control signal; at least one of the plurality of second sub-electrodes serves as a second touch-control electrode for transmitting a second touch-control signal; and, a first difference or a second difference is maintained between the first touch-control signal and the second touch-control signal, one of the first difference and the second difference is configured to maintain the transparent state of the light modulation structure, another of the first difference and the second difference is configured to maintain the opaque state of the light modulation structure.

19. The display apparatus as claimed in claim 15, wherein
the first insulating layer, one or more first scan touch-control electrodes, one or more first data touch-control electrodes, the second insulating layer, a first scan line, a third insulating layer, and a first data line are sequentially stacked on a side of the first electrode close to the first substrate; the one or more first scan touch-control electrodes and the one or more first data touch-control electrodes are distributed in an array, and the one or more first scan touch-control electrodes are insulated from the one or more first data touch-control electrodes, the one or more first scan touch-control electrodes in a same row are connected to a same first scan line, the one or more first data touch-control electrodes in a same column are connected to a same first data line;
a fourth insulating layer, one or more second scan touch-control electrodes, one or more second data touch-control electrodes, a fifth insulating layer, a second scan line, a sixth insulating layer, and a second data line are sequentially stacked on a side of the second electrode close to the second substrate; wherein the one or more second scan touch-control electrodes and the one or more second data touch-control electrodes are distributed in an array, and the one or more second scan touch-control electrodes are insulated from the one or more second data touch-control electrodes, the one or more second scan touch-control electrodes in a same row are connected to a same second scan line, the one or more second data touch-control electrodes in a same column are connected to a same second data line.

20. The display apparatus as claimed in claim 15, wherein
the light modulation structure comprises a first light modulation layer, a second light modulation layer, and a third light modulation layer; a sidewall at a side, where one of the plurality of first grooves and one of the plurality of second grooves are adjacent to each other, is the first light modulation layer, a bottom wall of the one of the plurality of first grooves close to the second substrate is the second light modulation layer, a bottom wall of the one of the plurality of second grooves close to the first substrate is the third light modulation layer; the light modulation structure comprises an opaque state and a transparent state; under an action of a same preset electric field, the transparent state of the second light modulation layer is reverse to that of the first light modulation layer, and the transparent state of the third light modulation layer is reverse to that of the first light modulation layer.
